(19) United States
(12) Patent Application Publication
(10) Pub. No.: US 2024/0121961 A1
(43) Pub. Date: Apr. 11, 2024

(54) METHOD OF MAKING A THREE-DIMENSIONAL MEMORY DEVICE USING DUAL WATER VAPOR FLOW OXIDATION AND APPARATUS FOR PERFORMING THE SAME

(71) Applicant: SANDISK TECHNOLOGIES LLC, ADDISON, TX (US)

(72) Inventors: Hiraku HASHIMOTO, Yokkaichi (JP); Eisuke TAKII, Yokkaichi (JP); Shin KOYAMA, Yokkaichi (JP)

(21) Appl. No.: 18/348,727

(22) Filed: Jul. 7, 2023

Related U.S. Application Data
(60) Provisional application No. 63/378,539, filed on Oct. 6, 2022.

(51) Int. Cl. H10B 43/27; H01L 21/673; H10B 41/27; H10B 41/35; H10B 43/35

(52) U.S. Cl. CPC H10B 43/27; H01L 21/67303; H10B 41/27; H10B 41/35; H10B 43/35; C23C 16/56

(57) ABSTRACT

A method includes forming a first portion of a layer over a substrate by flowing a reactant gas past the substrate in a first direction, and forming a second portion of the layer on the first portion of the layer by flowing the reactant gas past the substrate in a second direction different from the first direction.

### FIELD

The present disclosure relates generally to the field of semiconductor processing, and particularly to a method of making a three-dimensional memory device using dual water vapor flow oxidation and an apparatus for performing the same.

### BACKGROUND

A three-dimensional memory device including three-dimensional vertical NAND strings having one bit per cell are disclosed in an article by T. Endoh et al., titled “Novel Ultra High Density Memory With A Stacked-Surrounding Gate Transistor (S-SGT) Structured Cell”, IEDM Proc. (2001) 33-36.

### SUMMARY

According to an embodiment of the present disclosure, a method includes forming a first portion of a layer over a substrate by flowing a reactant gas past the substrate in a first direction, and forming a second portion of the layer on the first portion of the layer by flowing the reactant gas past the substrate in a second direction different from the first direction.

According to another embodiment of the present disclosure, an apparatus comprises a vacuum chamber extending in a first direction and having a first orifice located at a first end of the vacuum chamber and a second orifice located proximate to a second end of the vacuum chamber; a wafer boat extending along the first direction in the vacuum chamber and configured to hold wafers thereupon; a gas distribution conduit having a first gas outlet and a second gas outlet that are fluidly connected in parallel; a first gas flow switch fluidly connected to the first gas outlet and a first connection port fluidly connected to the first orifice; a second gas flow switch connected to the second gas outlet and a second connecting port fluidly connected to the second orifice; and a process controller configured to control the first gas flow switch and the second gas flow switch to provide a first gas flow configuration in which the reactant gas flows from the first gas outlet, through the first gas flow switch and the first connection port, and toward the first orifice; and a second gas flow configuration in which the reactant gas flows from the second gas outlet, through the second gas flow switch and the second connection port, and toward the second orifice.

### BRIEF DESCRIPTION OF THE DRAWINGS

FIG. 1A is a vertical cross-sectional view of an exemplary structure after formation of semiconductor devices, lower level dielectric layers, lower metal interconnect structures, and in-process source level material layers on a semiconductor substrate according to an embodiment of the present disclosure.

FIG. 1B is a top-down view of the exemplary structure of FIG. 1A. The hinged vertical plane A-A′ is the plane of the vertical cross-sectional view of FIG. 1A.

FIG. 1C is a magnified view of the in-process source level material layers along the vertical plane C-C′ of FIG. 1B.

FIG. 2 is a vertical cross-sectional view of the exemplary structure after formation of a first-tier alternating stack of first insulting layers and first spacer material layers according to an embodiment of the present disclosure.

FIG. 3 is a vertical cross-sectional view of the exemplary structure after patterning a first-tier staircase region, a first retro-stepped dielectric material portion, and an inter-tier dielectric layer according to an embodiment of the present disclosure.

FIG. 4A is a vertical cross-sectional view of the exemplary structure after formation of first-tier memory openings and first-tier support openings according to an embodiment of the present disclosure.

FIG. 4B is a horizontal cross-sectional view of the exemplary structure of FIG. 4A. The hinged vertical plane A-A′ corresponds to the plane of the vertical cross-sectional view of FIG. 4A.

FIG. 4C is a vertical cross-sectional view of a region around bottom portions of the first-tier memory openings in the exemplary structure of FIGS. 4A and 4B.

FIG. 5 is a vertical cross-sectional view of a region around bottom portions of the first-tier memory openings after formation of sacrificial semiconductor oxide portions according to an embodiment of the present disclosure.

FIG. 6A is a vertical cross-sectional view of an exemplary apparatus according to an embodiment of the present disclosure during a first processing step according to an embodiment of the present disclosure.

FIG. 6B is a graph illustrating a ratio of a water vapor partial pressure to a hydrogen partial pressure as a function of a vertical distance downward within a boat in a vacuum chamber of a vacuum enclosure in the exemplary apparatus during the first processing step in case an oxidation process is performed according to an embodiment of the present disclosure.

FIG. 6C is a graph illustrating an oxidation rate as a function of a vertical distance downward within a boat in a vacuum chamber of a vacuum enclosure in the exemplary apparatus during the first processing step in case an oxidation process is performed according to an embodiment of the present disclosure.

FIG. 7A is a vertical cross-sectional view of an exemplary apparatus according to an embodiment of the present disclosure during a second processing step according to an embodiment of the present disclosure.

FIG. 7B is a graph illustrating a ratio of a water vapor partial pressure to a hydrogen partial pressure as a function of a vertical distance downward within a boat in a vacuum chamber of a vacuum enclosure in the exemplary apparatus during the second processing step in case an oxidation process is performed according to an embodiment of the present disclosure.

FIG. 7C is a graph illustrating an oxidation rate as a function of a vertical distance downward within a boat in a vacuum chamber of a vacuum enclosure in the exemplary apparatus during the second processing step in case an oxidation process is performed according to an embodiment of the present disclosure.

FIG. 8A is a vertical cross-sectional view of the exemplary structure after formation of various sacrificial fill structures according to an embodiment of the present disclosure.

FIG. 8B is a vertical cross-sectional view of a region around bottom portions of sacrificial memory opening fill structures in the exemplary structure of FIGS. 4A and 4B.

FIG. 9 is a vertical cross-sectional view of the exemplary structure after formation of a second-tier alternating stack of second insulating layers and second spacer material layers, second stepped surfaces, and a second retro-stepped dielectric material portion according to an embodiment of the present disclosure.

FIG. 10A is a vertical cross-sectional view of the exemplary structure after formation of second-tier memory openings and second-tier support openings according to an embodiment of the present disclosure.

FIG. 10B is a horizontal cross-sectional view of the exemplary structure along the horizontal plane B-B′ of FIG. 10A. The hinged vertical plane A-A′ corresponds to the plane of the vertical cross-sectional view of FIG. 10A.

FIG. 11A is a vertical cross-sectional view of the exemplary structure after formation of inter-tier memory openings and inter-tier support openings according to an embodiment of the present disclosure.

FIG. 11B is a magnified view of a region of the exemplary structure of FIG. 11A around bottom portions of inter-tier memory openings.

FIG. 12 is a vertical cross-sectional view of a region of the exemplary structure around bottom portions of inter-tier memory openings after removal of the sacrificial semiconductor oxide portions according to an embodiment of the present disclosure.

FIGS. 13A-13D illustrate sequential vertical cross-sectional views of a memory opening during formation of a memory opening fill structure according to an embodiment of the present disclosure.

FIG. 14A is a vertical cross-sectional view of the exemplary structure after formation of memory opening fill structures and support pillar structures according to an embodiment of the present disclosure.

FIG. 14B is a horizontal cross-sectional view of the exemplary structure along the horizontal plane B-B′ of FIG. 14A. The hinged vertical plane A-A′ corresponds to the plane of the vertical cross-sectional view of FIG. 14A.

FIG. 15A is a vertical cross-sectional view of the exemplary structure after formation of a first contact-level dielectric layer and backside trenches according to an embodiment of the present disclosure.

FIG. 15B is a horizontal cross-sectional view of the exemplary structure along the horizontal plane B-B′ of FIG. 15A. The hinged vertical plane A-A′ corresponds to the plane of the vertical cross-sectional view of FIG. 15A.

FIG. 16 is a vertical cross-sectional view of the exemplary structure after formation of backside trench spacers according to an embodiment of the present disclosure.

FIGS. 17A-17E illustrate sequential vertical cross-sectional views of memory opening fill structures and a backside trench during formation of source-level material layers according to an embodiment of the present disclosure.

FIG. 18 is a vertical cross-sectional view of the exemplary structure after formation of source-level material layers according to an embodiment of the present disclosure.

FIG. 19 is a vertical cross-sectional view of the exemplary structure after formation of backside recesses according to an embodiment of the present disclosure.

FIG. 20A is a vertical cross-sectional view of the exemplary structure after formation of electrically conductive layers according to an embodiment of the present disclosure.

FIG. 20B is a horizontal cross-sectional view of the exemplary structure along the horizontal plane B-B′ of FIG. 20A. The hinged vertical plane A-A′ corresponds to the plane of the vertical cross-sectional view of FIG. 20A.

FIG. 21A is a vertical cross-sectional view of the exemplary structure after formation of backside trench fill structures in the backside trenches according to an embodiment of the present disclosure.

FIG. 21B is a horizontal cross-sectional view of the exemplary structure along the horizontal plane B-B′ of FIG. 21A. The hinged vertical plane A-A′ corresponds to the plane of the vertical cross-sectional view of FIG. 21A.

FIG. 22A is a vertical cross-sectional view of the exemplary structure after formation of a second contact-level dielectric layer and various contact via structures according to an embodiment of the present disclosure.

FIG. 22B is a horizontal cross-sectional view of the exemplary structure along the vertical plane B-B′ of FIG. 22A. The hinged vertical plane A-A′ corresponds to the plane of the vertical cross-sectional view of FIG. 22A.

FIG. 23 is a vertical cross-sectional view of the exemplary structure after formation of through-memory-level via structures and upper metal line structures according to an embodiment of the present disclosure.

### DETAILED DESCRIPTION

Oxidation of semiconductor materials, such as oxidation of silicon used to form silicon oxide may be limited by supply of a reactant gas, such as an oxidant. The growth rate of the silicon oxide can have wafer-to-wafer non-uniformity caused by a variation in the partial pressure of the oxidant gas in the oxidation apparatus. Embodiments of the present disclosure are directed to an oxidation processes employing two opposite reactant (e.g., oxidant) flow directions in the apparatus, which improves the wafer-to-wafer silicon oxide thickness uniformity, the various aspects of which are described herein in detail. The embodiments of the present disclosure may be used to form various semiconductor devices, such as three-dimensional memory devices comprising a plurality of NAND memory strings.

The drawings are not drawn to scale. Multiple instances of an element may be duplicated where a single instance of the element is illustrated, unless absence of duplication of elements is expressly described or clearly indicated otherwise. Ordinals such as “first,” “second,” and “third” are employed merely to identify similar elements, and different ordinals may be employed across the specification and the claims of the instant disclosure. The term “at least one” element refers to all possibilities including the possibility of a single element and the possibility of multiple elements.

The same reference numerals refer to the same element or similar element. Unless otherwise indicated, elements having the same reference numerals are presumed to have the same composition and the same function. Unless otherwise indicated, a “contact” between elements refers to a direct contact between elements that provides an edge or a surface shared by the elements. If two or more elements are not in direct contact with each other or among one another, the two elements are “disjoined from” each other or “disjoined among” one another. As used herein, a first element located “on” a second element can be located on the exterior side of a surface of the second element or on the interior side of the second element. As used herein, a first element is located “directly on” a second element if there exist a physical contact between a surface of the first element and a surface of the second element. As used herein, a first element is “electrically connected to” a second element if there exists a conductive path consisting of at least one conductive material between the first element and the second element. As used herein, a “prototype” structure or an “in-process” structure refers to a transient structure that is subsequently modified in the shape or composition of at least one component therein.

As used herein, a “layer” refers to a material portion including a region having a thickness. A layer may extend over the entirety of an underlying or overlying structure, or may have an extent less than the extent of an underlying or overlying structure. Further, a layer may be a region of a homogeneous or inhomogeneous continuous structure that has a thickness less than the thickness of the continuous structure. For example, a layer may be located between any pair of horizontal planes between, or at, a top surface and a bottom surface of the continuous structure. A layer may extend horizontally, vertically, and/or along a tapered surface. A substrate may be a layer, may include one or more layers therein, or may have one or more layer thereupon, thereabove, and/or therebelow.

As used herein, a first surface and a second surface are “vertically coincident” with each other if the second surface overlies or underlies the first surface and there exists a vertical plane or a substantially vertical plane that includes the first surface and the second surface. A substantially vertical plane is a plane that extends straight along a direction that deviates from a vertical direction by an angle less than 5 degrees. A vertical plane or a substantially vertical plane is straight along a vertical direction or a substantially vertical direction, and may, or may not, include a curvature along a direction that is perpendicular to the vertical direction or the substantially vertical direction.

As used herein, a “memory level” or a “memory array level” refers to the level corresponding to a general region between a first horizontal plane (i.e., a plane parallel to the top surface of the substrate) including topmost surfaces of an array of memory elements and a second horizontal plane including bottommost surfaces of the array of memory elements. As used herein, a “through-stack” element refers to an element that vertically extends through a memory level.

As used herein, a “semiconducting material” refers to a material having electrical conductivity in the range from 1.0×10⁻⁵ S/m to 1.0×10⁵ S/m. As used herein, a “semiconductor material” refers to a material having electrical conductivity in the range from 1.0×10⁻⁵ S/m to 1.0 S/m in the absence of electrical dopants therein, and is capable of producing a doped material having electrical conductivity in a range from 1.0 S/m to 1.0×10⁷ S/m upon suitable doping with an electrical dopant. As used herein, an “electrical dopant” refers to a p-type dopant that adds a hole to a valence band within a band structure, or an n-type dopant that adds an electron to a conduction band within a band structure. As used herein, a “conductive material” refers to a material having electrical conductivity greater than 1.0×10⁵ S/m. As used herein, an “insulator material” or a “dielectric material” refers to a material having electrical conductivity less than 1.0×10⁻⁵ S/m. As used herein, a “heavily doped semiconductor material” refers to a semiconductor material that is doped with electrical dopant at a sufficiently high atomic concentration to become a conductive material either as formed as a crystalline material or if converted into a crystalline material through an anneal process (for example, from an initial amorphous state), i.e., to provide electrical conductivity greater than 1.0×10⁵ S/m. A “doped semiconductor material” may be a heavily doped semiconductor material, or may be a semiconductor material that includes electrical dopants (i.e., p-type dopants and/or n-type dopants) at a concentration that provides electrical conductivity in the range from 1.0×10⁻⁵ S/m to 1.0×10⁷ S/m. An “intrinsic semiconductor material” refers to a semiconductor material that is not doped with electrical dopants. Thus, a semiconductor material may be semiconducting or conductive, and may be an intrinsic semiconductor material or a doped semiconductor material. A doped semiconductor material may be semiconducting or conductive depending on the atomic concentration of electrical dopants therein. As used herein, a “metallic material” refers to a conductive material including at least one metallic element therein. All measurements for electrical conductivities are made at the standard condition.

A monolithic three-dimensional memory array is one in which multiple memory levels are formed above a single substrate, such as a semiconductor wafer, with no intervening substrates. The term “monolithic” means that layers of each level of the array are directly deposited on the layers of each underlying level of the array. In contrast, two dimensional arrays may be formed separately and then packaged together to form a non-monolithic memory device. For example, non-monolithic stacked memories have been constructed by forming memory levels on separate substrates and vertically stacking the memory levels, as described in U.S. Pat. No. 5,915,167 titled “Three-dimensional Structure Memory.” The substrates may be thinned or removed from the memory levels before bonding, but as the memory levels are initially formed over separate substrates, such memories are not true monolithic three-dimensional memory arrays. The substrate may include integrated circuits fabricated thereon, such as driver circuits for a memory device

The various three-dimensional memory devices of the present disclosure include a monolithic three-dimensional NAND string memory device, and may be fabricated using the various embodiments described herein. The monolithic three-dimensional NAND string is located in a monolithic, three-dimensional array of NAND strings located over the substrate. At least one memory cell in the first device level of the three-dimensional array of NAND strings is located over another memory cell in the second device level of the three-dimensional array of NAND strings.

Generally, a semiconductor package (or a “package”) refers to a unit semiconductor device that may be attached to a circuit board through a set of pins or solder balls. A semiconductor package may include a semiconductor chip (or a “chip”) or a plurality of semiconductor chips that are bonded throughout, for example, by flip-chip bonding or another chip-to-chip bonding. A package or a chip may include a single semiconductor die (or a “die”) or a plurality of semiconductor dies. A die is the smallest unit that may independently execute external commands or report status. Typically, a package or a chip with multiple dies is capable of simultaneously executing as many number of external commands as the total number of dies therein. Each die includes one or more planes. Identical concurrent operations may be executed in each plane within a same die, although there may be some restrictions. In case a die is a memory die, i.e., a die including memory elements, concurrent read operations, concurrent write operations, or concurrent erase operations may be performed in each plane within a same memory die. In a memory die, each plane contains a number of memory blocks (or “blocks”), which are the smallest unit that may be erased by in a single erase operation. Each memory block contains a number of pages, which are the smallest units that may be selected for programming. A page is also the smallest unit that may be selected to a read operation.

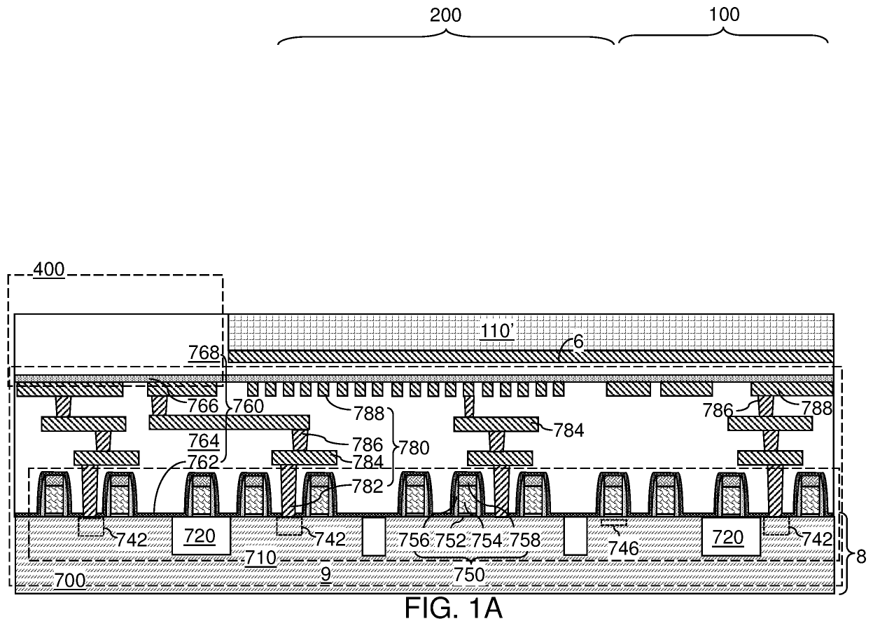

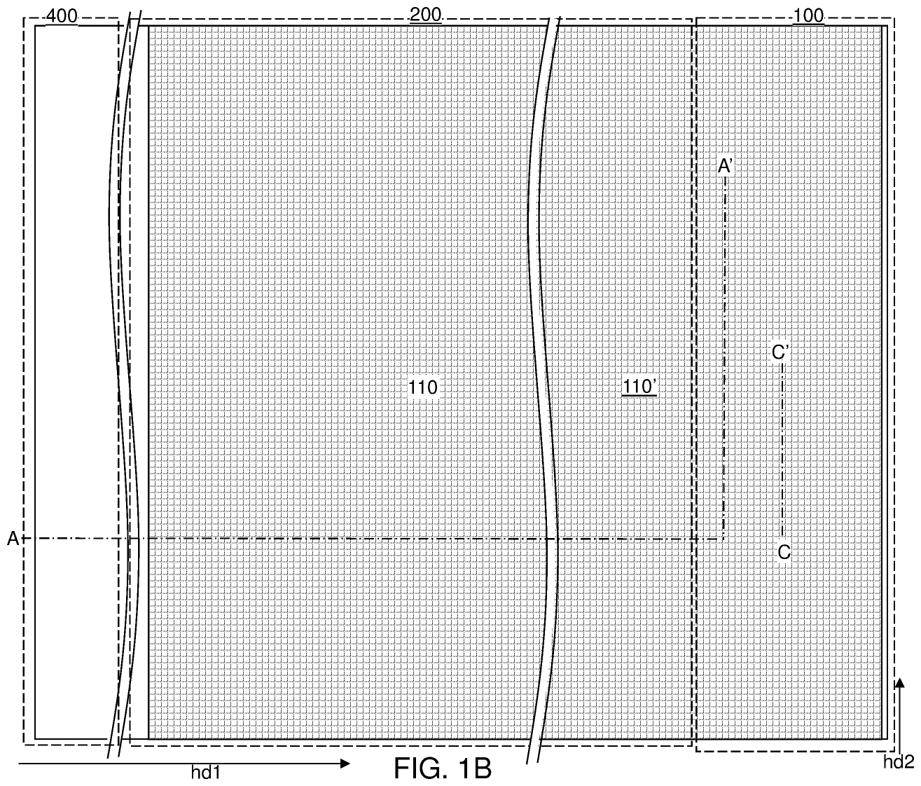

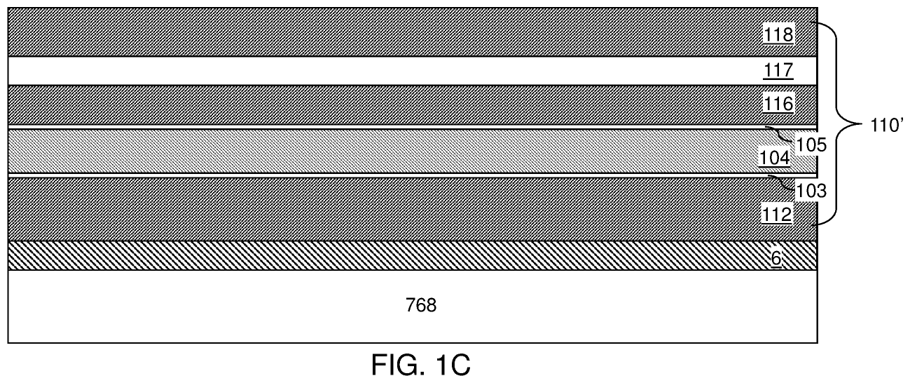

Referring to FIGS. 1A-1C, an exemplary structure according to an embodiment of the present disclosure is illustrated. FIG. 1C is a magnified view of an in-process source-level material layers 110′ illustrated in FIGS. 1A and 1B. The exemplary structure includes a substrate 8 and semiconductor devices 710 formed thereupon. The substrate 8 includes a substrate semiconductor layer 9 at least at an upper portion thereof. Shallow trench isolation structures 720 may be formed in an upper portion of the substrate semiconductor layer 9 to provide electrical isolation from other semiconductor devices. The semiconductor devices 710 may include, for example, field effect transistors including respective transistor active regions 742 (i.e., source regions and drain regions), channel regions 746, and gate structures 750. The field effect transistors may be arranged in a CMOS configuration. Each gate structure 750 may include, for example, a gate dielectric 752, a gate electrode 754, a dielectric gate spacer 756 and a gate cap dielectric 758. The semiconductor devices 710 may include any semiconductor circuitry to support operation of a memory structure to be subsequently formed, which is typically referred to as a driver circuitry, which is also known as peripheral circuitry. As used herein, a peripheral circuitry refers to any, each, or all, of word line decoder circuitry, word line switching circuitry, bit line decoder circuitry, bit line sensing and/or switching circuitry, power supply/distribution circuitry, data buffer and/or latch, or any other semiconductor circuitry that may be implemented outside a memory array structure for a memory device. For example, the semiconductor devices may include word line switching devices for electrically biasing word lines of three-dimensional memory structures to be subsequently formed.

Dielectric material layers are formed over the semiconductor devices, which are herein referred to as lower-level dielectric material layers 760. The lower-level dielectric material layers 760 may include, for example, a dielectric liner 762 (such as a silicon nitride liner that blocks diffusion of mobile ions and/or apply appropriate stress to underlying structures), first dielectric material layers 764 that overlie the dielectric liner 762, a silicon nitride layer (e.g., hydrogen diffusion barrier) 766 that overlies the first dielectric material layers 764, and at least one second dielectric layer 768.

The dielectric layer stack including the lower-level dielectric material layers 760 functions as a matrix for lower-level metal interconnect structures 780 that provide electrical wiring to and from the various nodes of the semiconductor devices and landing pads for through-memory-level contact via structures to be subsequently formed. The lower-level metal interconnect structures 780 are formed within the dielectric layer stack of the lower-level dielectric material layers 760, and comprise a lower-level metal line structure located under and optionally contacting a bottom surface of the silicon nitride layer 766.

For example, the lower-level metal interconnect structures 780 may be formed within the first dielectric material layers 764. The first dielectric material layers 764 may be a plurality of dielectric material layers in which various elements of the lower-level metal interconnect structures 780 are sequentially formed. Each dielectric material layer selected from the first dielectric material layers 764 may include any of doped silicate glass, undoped silicate glass, organosilicate glass, silicon nitride, silicon oxynitride, and dielectric metal oxides (such as aluminum oxide). In one embodiment, the first dielectric material layers 764 may comprise, or consist essentially of, dielectric material layers having dielectric constants that do not exceed the dielectric constant of undoped silicate glass (silicon oxide) of 3.9. The lower-level metal interconnect structures 780 may include various device contact via structures 782 (e.g., source and drain electrodes which contact the respective source and drain nodes of the device or gate electrode contacts), intermediate lower-level metal line structures 784, lower-level metal via structures 786, and landing-pad-level metal line structures 788 that are configured to function as landing pads for through-memory-level contact via structures to be subsequently formed.

The landing-pad-level metal line structures 788 may be formed within a topmost dielectric material layer of the first dielectric material layers 764 (which may be a plurality of dielectric material layers). Each of the lower-level metal interconnect structures 780 may include a metallic nitride liner and a metal fill structure. Top surfaces of the landing-pad-level metal line structures 788 and the topmost surface of the first dielectric material layers 764 may be planarized by a planarization process, such as chemical mechanical planarization. The silicon nitride layer 766 may be formed directly on the top surfaces of the landing-pad-level metal line structures 788 and the topmost surface of the first dielectric material layers 764.

The at least one second dielectric material layer 768 may include a single dielectric material layer or a plurality of dielectric material layers. Each dielectric material layer selected from the at least one second dielectric material layer 768 may include any of doped silicate glass, undoped silicate glass, and organosilicate glass. In one embodiment, the at least one first second material layer 768 may comprise, or consist essentially of, dielectric material layers having dielectric constants that do not exceed the dielectric constant of undoped silicate glass (silicon oxide) of 3.9.

An optional layer of a metallic material and a layer of a semiconductor material may be deposited over, or within patterned recesses of, the at least one second dielectric material layer 768, and is lithographically patterned to provide an optional conductive plate layer 6 and in-process source-level material layers 110′. The optional conductive plate layer 6, if present, provides a high conductivity conduction path for electrical current that flows into, or out of, the in-process source-level material layers 110′. The optional conductive plate layer 6 includes a conductive material such as a metal or a heavily doped semiconductor material. The optional conductive plate layer 6, for example, may include a tungsten layer having a thickness in a range from 3 nm to 100 nm, although lesser and greater thicknesses may also be used. A metal nitride layer (not shown) may be provided as a diffusion barrier layer on top of the conductive plate layer 6. The conductive plate layer 6 may function as a special source line in the completed device. In addition, the conductive plate layer 6 may comprise an etch stop layer and may comprise any suitable conductive, semiconductor or insulating layer. The optional conductive plate layer 6 may include a metallic compound material such as a conductive metallic nitride (e.g., TiN) and/or a metal (e.g., W). The thickness of the optional conductive plate layer 6 may be in a range from 5 nm to 100 nm, although lesser and greater thicknesses may also be used.

The in-process source-level material layers 110′ may include various layers that are subsequently modified to form source-level material layers. The source-level material layers, upon formation, include a source contact layer that functions as a common source region for vertical field effect transistors of a three-dimensional memory device. In one embodiment, the in-process source-level material layers 110′ may include, from bottom to top, a lower source-level semiconductor layer 112, a lower sacrificial liner 103, a source-level sacrificial layer 104, an upper sacrificial liner 105, an upper source-level semiconductor layer 116, a source-level insulating layer 117, and an optional source-select-level conductive layer 118.

The lower source-level semiconductor layer 112 and the upper source-level semiconductor layer 116 may include a doped semiconductor material such as doped polysilicon or doped amorphous silicon. The conductivity type of the lower source-level semiconductor layer 112 and the upper source-level semiconductor layer 116 may be the opposite of the conductivity of vertical semiconductor channels to be subsequently formed. For example, if the vertical semiconductor channels to be subsequently formed have a doping of a first conductivity type, the lower source-level semiconductor layer 112 and the upper source-level semiconductor layer 116 have a doping of a second conductivity type that is the opposite of the first conductivity type. The thickness of each of the lower source-level semiconductor layer 112 and the upper source-level semiconductor layer 116 may be in a range from 10 nm to 300 nm, such as from 20 nm to 150 nm, although lesser and greater thicknesses may also be used.

The source-level sacrificial layer 104 includes a sacrificial material that may be removed selective to the lower sacrificial liner 103 and the upper sacrificial liner 105. In one embodiment, the source-level sacrificial layer 104 may include silicon nitride. The thickness of the source-level sacrificial layer 104 may be in a range from 20 nm to 120 nm, such as from 30 nm to 80 nm, although lesser and greater thicknesses may also be used.

The lower sacrificial liner 103 and the upper sacrificial liner 105 include materials that may function as an etch stop material during removal of the source-level sacrificial layer 104. For example, the lower sacrificial liner 103 and the upper sacrificial liner 105 may include silicon oxide, silicon nitride, and/or a dielectric metal oxide. In one embodiment, each of the lower sacrificial liner 103 and the upper sacrificial liner 105 may include a silicon oxide layer having a thickness in a range from 2 nm to 30 nm, although lesser and greater thicknesses may also be used.

The source-level insulating layer 117 includes a dielectric material such as silicon oxide. The thickness of the source-level insulating layer 117 may be in a range from 20 nm to 400 nm, such as from 40 nm to 200 nm, although lesser and greater thicknesses may also be used. The optional source-select-level conductive layer 118 may include a conductive material that may be used as a source-select-level gate electrode. For example, the optional source-select-level conductive layer 118 may include a doped semiconductor material such as doped polysilicon or doped amorphous silicon that may be subsequently converted into doped polysilicon by an anneal process. The thickness of the optional source-select-level conductive layer 118 may be in a range from 30 nm to 200 nm, such as from 60 nm to 100 nm, although lesser and greater thicknesses may also be used.

The in-process source-level material layers 110′ may be formed directly above a subset of the semiconductor devices on the substrate 8 (e.g., silicon wafer). As used herein, a first element is located “directly above” a second element if the first element is located above a horizontal plane including a topmost surface of the second element and an area of the first element and an area of the second element has an areal overlap in a plan view (i.e., along a vertical plane or direction perpendicular to the top surface of the substrate 8.

The optional conductive plate layer 6 and the in-process source-level material layers 110′ may be patterned to provide openings in areas in which through-memory-level contact via structures and through-dielectric contact via structures are to be subsequently formed. Patterned portions of the stack of the conductive plate layer 6 and the in-process source-level material layers 110′ are present in each memory array region 100 in which three-dimensional memory stack structures are to be subsequently formed.

The optional conductive plate layer 6 and the in-process source-level material layers 110′ may be patterned such that an opening extends over a staircase region 200 in which contact via structures contacting word line electrically conductive layers are to be subsequently formed. In one embodiment, the staircase region 200 may be laterally spaced from the memory array region 100 along a first horizontal direction hd1. A horizontal direction that is perpendicular to the first horizontal direction hd1 is herein referred to as a second horizontal direction hd2. In one embodiment, additional openings in the optional conductive plate layer 6 and the in-process source-level material layers 110′ may be formed within the area of a memory array region 100, in which a three-dimensional memory array including memory stack structures is to be subsequently formed. A peripheral device region 400 that is subsequently filled with a field dielectric material portion may be provided adjacent to the staircase region 200.

The region of the semiconductor devices 710 and the combination of the lower-level dielectric material layers 760 and the lower-level metal interconnect structures 780 is herein referred to an underlying peripheral device region 700, which is located underneath a memory-level assembly to be subsequently formed and includes peripheral devices for the memory-level assembly. The lower-level metal interconnect structures 780 are formed in the lower-level dielectric material layers 760.

The lower-level metal interconnect structures 780 may be electrically connected to active nodes (e.g., transistor active regions 742 or gate electrodes 754) of the semiconductor devices 710 (e.g., CMOS devices), and are located at the level of the lower-level dielectric material layers 760. Through-memory-level contact via structures may be subsequently formed directly on the lower-level metal interconnect structures 780 to provide electrical connection to memory devices to be subsequently formed. In one embodiment, the pattern of the lower-level metal interconnect structures 780 may be selected such that the landing-pad-level metal line structures 788 (which are a subset of the lower-level metal interconnect structures 780 located at the topmost portion of the lower-level metal interconnect structures 780) may provide landing pad structures for the through-memory-level contact via structures to be subsequently formed.

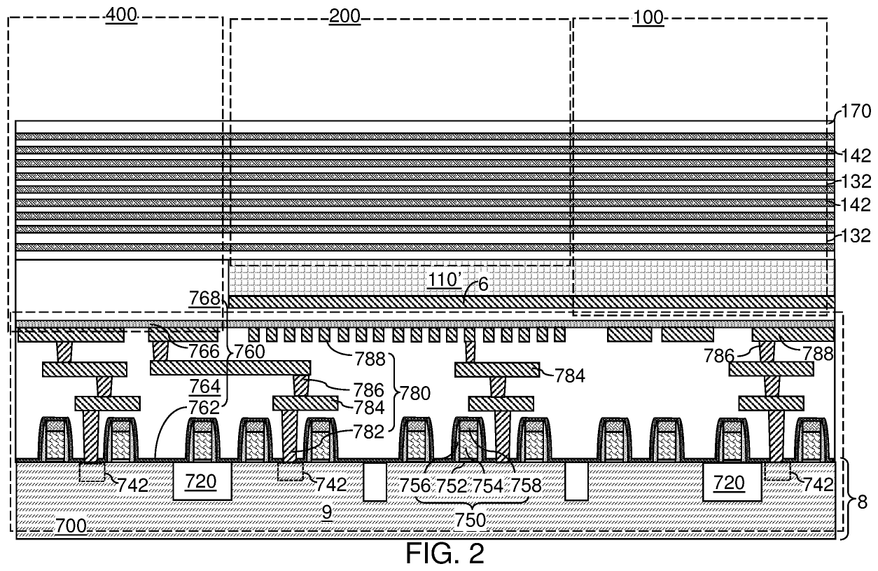

Referring to FIG. 2, an alternating stack of first material layers and second material layers is subsequently formed. Each first material layer may include a first material, and each second material layer may include a second material that is different from the first material. In case at least another alternating stack of material layers is subsequently formed over the alternating stack of the first material layers and the second material layers, the alternating stack is herein referred to as a first-tier alternating stack. The level of the first-tier alternating stack is herein referred to as a first-tier level, and the level of the alternating stack to be subsequently formed immediately above the first-tier level is herein referred to as a second-tier level, etc.

The first-tier alternating stack may include first insulting layers 132 as the first material layers, and first spacer material layers as the second material layers. In one embodiment, the first spacer material layers may be sacrificial material layers that are subsequently replaced with electrically conductive layers. In another embodiment, the first spacer material layers may be electrically conductive layers that are not subsequently replaced with other layers. While the present disclosure is described using embodiments in which sacrificial material layers are replaced with electrically conductive layers, embodiments in which the spacer material layers are formed as electrically conductive layers (thereby obviating the need to perform replacement processes) are expressly contemplated herein.

In one embodiment, the first material layers and the second material layers may be first insulating layers 132 and first sacrificial material layers 142, respectively. In one embodiment, each first insulating layer 132 may include a first insulating material, and each first sacrificial material layer 142 may include a first sacrificial material. An alternating plurality of first insulating layers 132 and first sacrificial material layers 142 is formed over the in-process source-level material layers 110′. As used herein, a “sacrificial material” refers to a material that is removed during a subsequent processing step.

As used herein, an alternating stack of first elements and second elements refers to a structure in which instances of the first elements and instances of the second elements alternate. Each instance of the first elements that is not an end element of the alternating plurality is adjoined by two instances of the second elements on both sides, and each instance of the second elements that is not an end element of the alternating plurality is adjoined by two instances of the first elements on both ends. The first elements may have the same thickness throughout, or may have different thicknesses. The second elements may have the same thickness throughout, or may have different thicknesses. The alternating plurality of first material layers and second material layers may begin with an instance of the first material layers or with an instance of the second material layers, and may end with an instance of the first material layers or with an instance of the second material layers. In one embodiment, an instance of the first elements and an instance of the second elements may form a unit that is repeated with periodicity within the alternating plurality.

The first-tier alternating stack (132, 142) may include first insulating layers 132 composed of the first material, and first sacrificial material layers 142 composed of the second material, which is different from the first material. The first material of the first insulating layers 132 may be at least one insulating material. Insulating materials that may be used for the first insulating layers 132 include, but are not limited to silicon oxide (including doped or undoped silicate glass), silicon nitride, silicon oxynitride, organosilicate glass (OSG), spin-on dielectric materials, dielectric metal oxides that are commonly known as high dielectric constant (high-k) dielectric oxides (e.g., aluminum oxide, hafnium oxide, etc.) and silicates thereof, dielectric metal oxynitrides and silicates thereof, and organic insulating materials. In one embodiment, the first material of the first insulating layers 132 may be silicon oxide.

The second material of the first sacrificial material layers 142 is a sacrificial material that may be removed selective to the first material of the first insulating layers 132. As used herein, a removal of a first material is “selective to” a second material if the removal process removes the first material at a rate that is at least twice the rate of removal of the second material. The ratio of the rate of removal of the first material to the rate of removal of the second material is herein referred to as a “selectivity” of the removal process for the first material with respect to the second material.

The first sacrificial material layers 142 may comprise an insulating material, a semiconductor material, or a conductive material. The second material of the first sacrificial material layers 142 may be subsequently replaced with electrically conductive electrodes which may function, for example, as control gate electrodes of a vertical NAND device. In one embodiment, the first sacrificial material layers 142 may be material layers that comprise silicon nitride.

In one embodiment, the first insulating layers 132 may include silicon oxide, and sacrificial material layers may include silicon nitride sacrificial material layers. The first material of the first insulating layers 132 may be deposited, for example, by chemical vapor deposition (CVD). For example, if silicon oxide is used for the first insulating layers 132, tetraethylorthosilicate (TEOS) may be used as the precursor material for the CVD process. The second material of the first sacrificial material layers 142 may be formed, for example, CVD or atomic layer deposition (ALD).

The thicknesses of the first insulating layers 132 and the first sacrificial material layers 142 may be in a range from 20 nm to 50 nm, although lesser and greater thicknesses may be used for each first insulating layer 132 and for each first sacrificial material layer 142. The number of repetitions of the pairs of a first insulating layer 132 and a first sacrificial material layer 142 may be in a range from 2 to 1,024, and typically from 8 to 256, although a greater number of repetitions may also be used. In one embodiment, each first sacrificial material layer 142 in the first-tier alternating stack (132, 142) may have a uniform thickness that is substantially invariant within each respective first sacrificial material layer 142.

A first insulating cap layer 170 is subsequently formed over the first-tier alternating stack (132, 142). The first insulating cap layer 170 includes a dielectric material, which may be any dielectric material that may be used for the first insulating layers 132. In one embodiment, the first insulating cap layer 170 includes the same dielectric material as the first insulating layers 132. The thickness of the first insulating cap layer 170 may be in a range from 20 nm to 300 nm, although lesser and greater thicknesses may also be used.

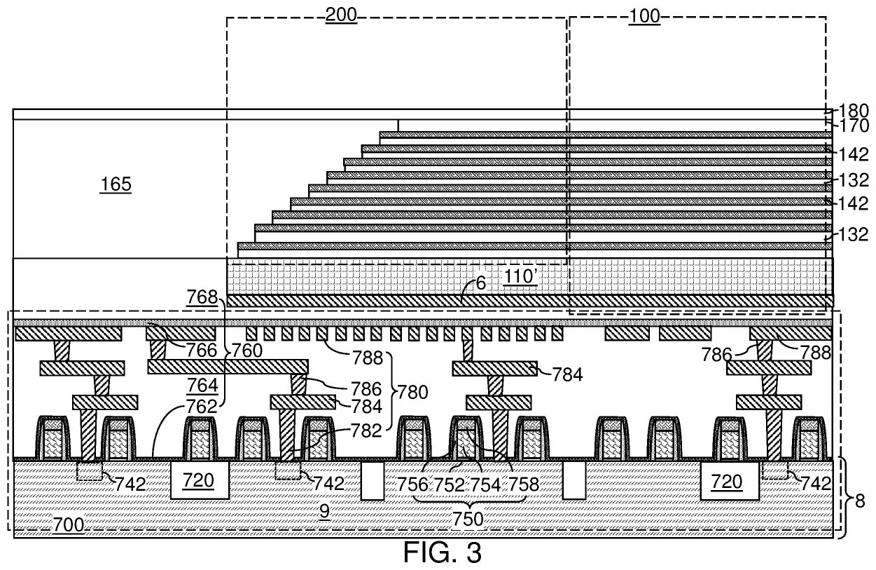

Referring to FIG. 3, the first insulating cap layer 170 and the first-tier alternating stack (132, 142) may be patterned to form first stepped surfaces in the staircase region 200. The staircase region 200 may include a respective first stepped area in which the first stepped surfaces are formed, and a second stepped area in which additional stepped surfaces are to be subsequently formed in a second-tier structure (to be subsequently formed over a first-tier structure) and/or additional tier structures. The first stepped surfaces may be formed, for example, by forming a mask layer (not shown) with an opening therein, etching a cavity within the levels of the first insulating cap layer 170, and iteratively expanding the etched area and vertically recessing the cavity by etching each pair of a first insulating layer 132 and a first sacrificial material layer 142 located directly underneath the bottom surface of the etched cavity within the etched area. In one embodiment, top surfaces of the first sacrificial material layers 142 may be physically exposed at the first stepped surfaces. The cavity overlying the first stepped surfaces is herein referred to as a first stepped cavity.

A dielectric fill material (such as undoped silicate glass or doped silicate glass) may be deposited to fill the first stepped cavity. Excess portions of the dielectric fill material may be removed from above the horizontal plane including the top surface of the first insulating cap layer 170. A remaining portion of the dielectric fill material that fills the region overlying the first stepped surfaces constitute a first retro-stepped dielectric material portion 165. As used herein, a “retro-stepped” element refers to an element that has stepped surfaces and a horizontal cross-sectional area that increases monotonically as a function of a vertical distance from a top surface of a substrate on which the element is present. The first-tier alternating stack (132, 142) and the first retro-stepped dielectric material portion 165 collectively constitute a first-tier structure, which is an in-process structure that is subsequently modified.

An inter-tier dielectric layer 180 may be optionally deposited over the first-tier structure (132, 142, 170, 165). The inter-tier dielectric layer 180 includes a dielectric material such as silicon oxide. In one embodiment, the inter-tier dielectric layer 180 may include a doped silicate glass having a greater etch rate than the material of the first insulating layers 132 (which may include an undoped silicate glass). For example, the inter-tier dielectric layer 180 may include phosphosilicate glass. The thickness of the inter-tier dielectric layer 180 may be in a range from 30 nm to 300 nm, although lesser and greater thicknesses may also be used.

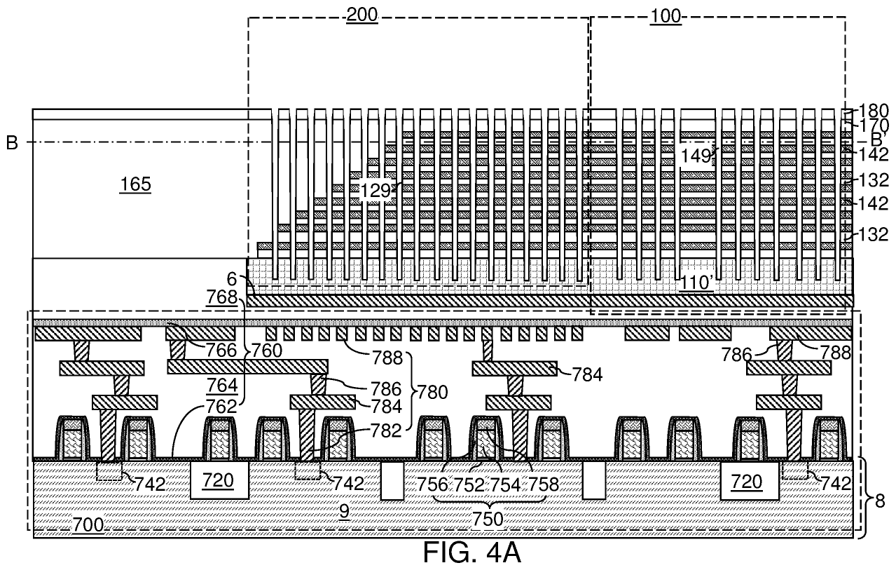

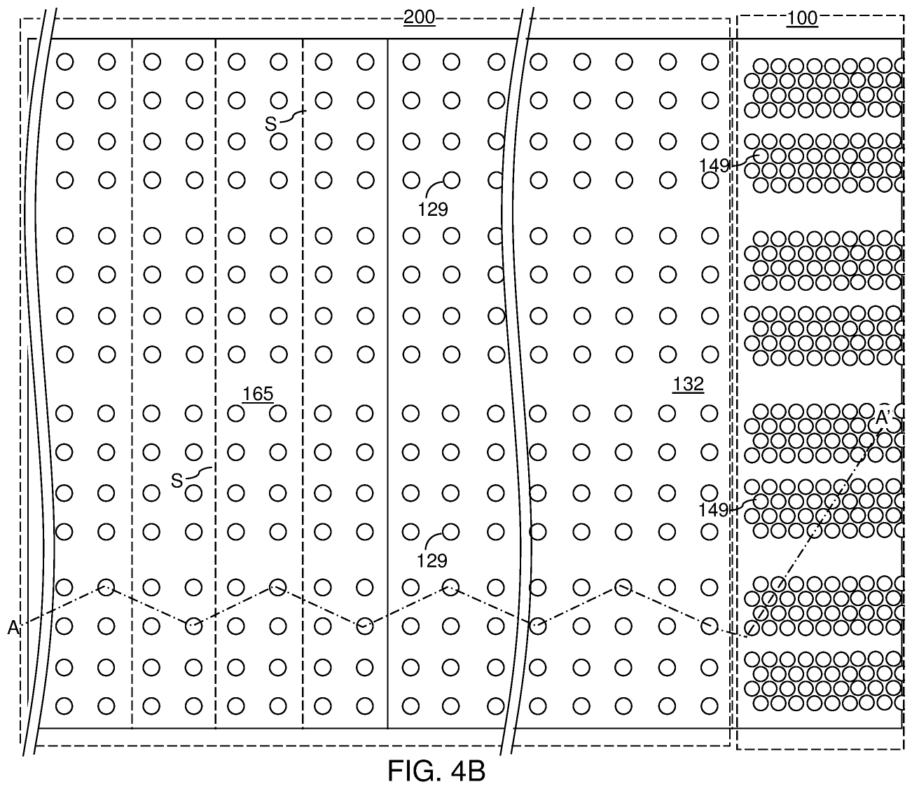

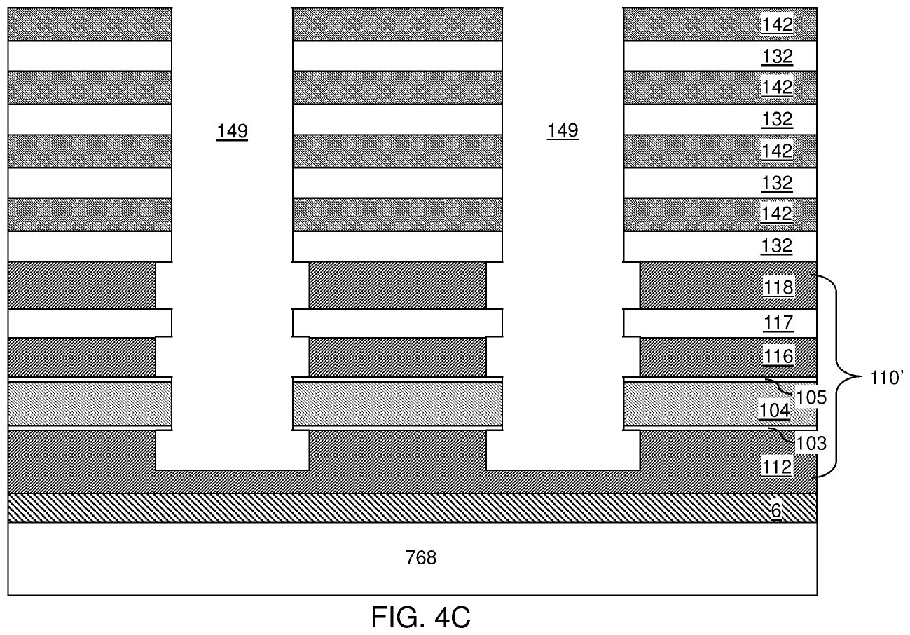

Referring to FIGS. 4A and 4B, various first-tier openings (149, 129) may be formed through the inter-tier dielectric layer 180 and the first-tier structure (132, 142, 170, 165) and into the in-process source-level material layers 110′. A photoresist layer (not shown) may be applied over the inter-tier dielectric layer 180, and may be lithographically patterned to form various openings therethrough. The pattern of openings in the photoresist layer may be transferred through the inter-tier dielectric layer 180 and the first-tier structure (132, 142, 170, 165) and into the in-process source-level material layers 110′ by a first anisotropic etch process to form the various first-tier openings (149, 129) concurrently, i.e., during the first isotropic etch process. The various first-tier openings (149, 129) may include first-tier memory openings 149 and first-tier support openings 129. Locations of steps S in the first-tier alternating stack (132, 142) are illustrated as dotted lines in FIG. 4B.

The first-tier memory openings 149 are openings that are formed in the memory array region 100 through each layer within the first-tier alternating stack (132, 142) and are subsequently used to form memory stack structures therein. The first-tier memory openings 149 may be formed in clusters of first-tier memory openings 149 that are laterally spaced apart along the second horizontal direction hd2. Each cluster of first-tier memory openings 149 may be formed as a two-dimensional array of first-tier memory openings 149.

The first-tier support openings 129 are openings that are formed in the staircase region 200, and are subsequently employed to form support pillar structures. A subset of the first-tier support openings 129 that is formed through the first retro-stepped dielectric material portion 165 may be formed through a respective horizontal surface of the first stepped surfaces.

In one embodiment, the first anisotropic etch process may include an initial step in which the materials of the first-tier alternating stack (132, 142) are etched concurrently with the material of the first retro-stepped dielectric material portion 165. The chemistry of the initial etch step may alternate to optimize etching of the first and second materials in the first-tier alternating stack (132, 142) while providing a comparable average etch rate to the material of the first retro-stepped dielectric material portion 165. The first anisotropic etch process may use, for example, a series of reactive ion etch processes or a single reaction etch process (e.g., CF₄/O₂/Ar etch). The sidewalls of the various first-tier openings (149, 129) may be substantially vertical, or may be tapered.

After etching through the alternating stack (132, 142) and the first retro-stepped dielectric material portion 165, the chemistry of a terminal portion of the first anisotropic etch process may be selected to etch through the dielectric material(s) of the at least one second dielectric layer 768 with a higher etch rate than an average etch rate for the in-process source-level material layers 110′. For example, the terminal portion of the anisotropic etch process may include a step that etches the dielectric material(s) of the at least one second dielectric layer 768 selective to a semiconductor material within a component layer in the in-process source-level material layers 110′. In one embodiment, the terminal portion of the first anisotropic etch process may etch through the source-select-level conductive layer 118, the source-level insulating layer 117, the upper source-level semiconductor layer 116, the upper sacrificial liner 105, the source-level sacrificial layer 104, and the lower sacrificial liner 103, and at least partly into the lower source-level semiconductor layer 112. The terminal portion of the first anisotropic etch process may include at least one etch chemistry for etching the various semiconductor materials of the in-process source-level material layers 110′. The photoresist layer may be subsequently removed, for example, by ashing.

Optionally, the portions of the first-tier memory openings 149 and the first-tier support openings 129 at the level of the inter-tier dielectric layer 180 may be laterally expanded by an isotropic etch. In this case, the inter-tier dielectric layer 180 may comprise a dielectric material (such as borosilicate glass) having a greater etch rate than the first insulating layers 132 (that may include undoped silicate glass) in dilute hydrofluoric acid. An isotropic etch (such as a wet etch using HF) may be used to expand the lateral dimensions of the first-tier memory openings 149 at the level of the inter-tier dielectric layer 180. The portions of the first-tier memory openings 149 located at the level of the inter-tier dielectric layer 180 may be optionally widened to provide a larger landing pad for second-tier memory openings to be subsequently formed through a second-tier alternating stack (to be subsequently formed prior to formation of the second-tier memory openings).

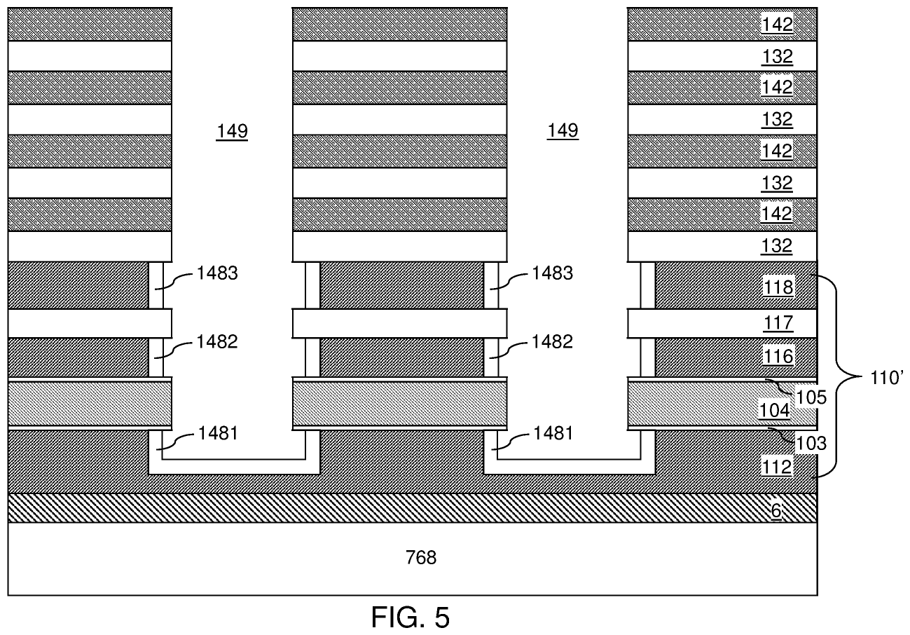

Referring to FIG. 5, an oxidation process can be performed to convert physically exposed surface portions of the semiconductor material layers into sacrificial semiconductor oxide portions (1481, 1482, 1483). For example, if the semiconductor material layers comprise polysilicon or amorphous silicon, then the sacrificial semiconductor oxide portions comprise silicon oxide portions. A first sacrificial semiconductor oxide portion 1481 may be formed on the lower source-level semiconductor layer 112 at the bottom of each first-tier memory opening 149, and a second sacrificial semiconductor oxide portion 1482 may be formed on the upper source-level semiconductor layer 116 at the bottom of each first-tier memory opening 149. If a source-select-level conductive layer 118 is present and comprises a semiconductor material such as silicon, a third sacrificial semiconductor oxide portion 1483 may be formed on the source-select-level conductive layer 118 at the bottom of each first-tier memory opening 149. In case the lower source-level semiconductor layer 112, the upper source-level semiconductor layer 116, and the source-select-level conductive layer 118 comprise silicon, the various sacrificial semiconductor oxide portions (1481, 1482, 1483) may comprise silicon oxide.

On one hand, the thickness of the sacrificial semiconductor oxide portions (1481, 1482, 1483) is preferably limited in order to minimize collateral expansion of the bottom portion of each first-tier memory opening 149 upon subsequent removal of the sacrificial semiconductor oxide portions (1481, 1482, 1483). On the other hand, the sacrificial semiconductor oxide portions (1481, 1482, 1483) need to be sufficiently thick so that formation of pinholes can be avoided during subsequent etching step(s). Pinholes through the sacrificial semiconductor oxide portions (1481, 1482, 1483) can cause undesirable penetration of an etchant during a subsequent isotropic etch process (such as a wet etch process) that is employed to remove sacrificial opening fill material portions that are formed inside the sacrificial semiconductor oxide portions (1481, 1482, 1483). Once the etchant penetrates through the sacrificial semiconductor oxide portions (1481, 1482, 1483) into the lower source-level semiconductor layer 112, the upper source-level semiconductor layer 116, and/or the source-select-level conductive layer 118, then the materials of the lower source-level semiconductor layer 112, the upper source-level semiconductor layer 116, and the source-select-level conductive layer 118 can be undesirably collaterally etched during removal of the material of the sacrificial opening fill material portions from inside the sacrificial semiconductor oxide portions (1481, 1482, 1483). Thus, it is desirable to form the sacrificial semiconductor oxide portions (1481, 1482, 1483) with a uniform thickness within a target thickness range, which may be in range from 2 to 3 nm. If the thickness is below 2 nm, then undesirable pinholes may occur during subsequent etching step(s).

The inventors observed that the thickness of the sacrificial semiconductor oxide portions (1481, 1482, 1483) can have a thickness variation as a function of a position of the wafer (i.e., substrate 8) in an oxidation apparatus. Generally, the thickness of the sacrificial semiconductor oxide portions (1481, 1482, 1483) is higher on a wafer located in proximity to a gas inlet for an oxidant gas than on a wafer located in proximity to the exhaust for the oxidation gas. The partial pressure of the oxidant gas (such as water vapor) is higher near the gas inlet than near the exhaust, and the partial pressure of hydrogen gas (e.g., hydrogen outgassed from the silicon nitride sacrificial material layers 142 during the oxidation process) is higher near the exhaust than near the gas inlet. The outgassed hydrogen flows in the same direction as the oxidant gas and dilutes the oxidant gas (e.g., water vapor) to a more significant degree for wafers located closer to the exhaust than for the wafers located farther from the exhaust, since the mixed hydrogen—oxidant stream picks up additional outgassed hydrogen from each wafer on the way to the exhaust. This results in a difference in thickness of the sacrificial semiconductor oxide portions. Thus, the sacrificial semiconductor oxide portions formed on wafers located closer to the exhaust may not be sufficiently thick (e.g., may be thinner than 2 nm), and may suffer from the undesirable pinhole formation.

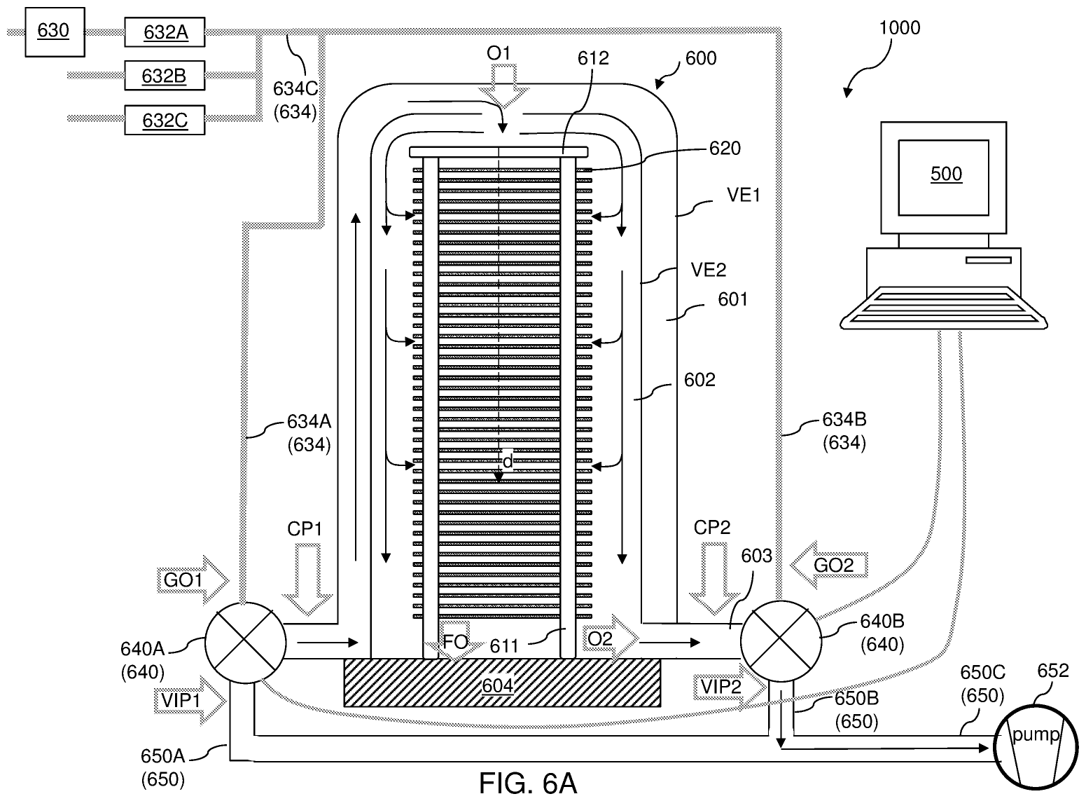

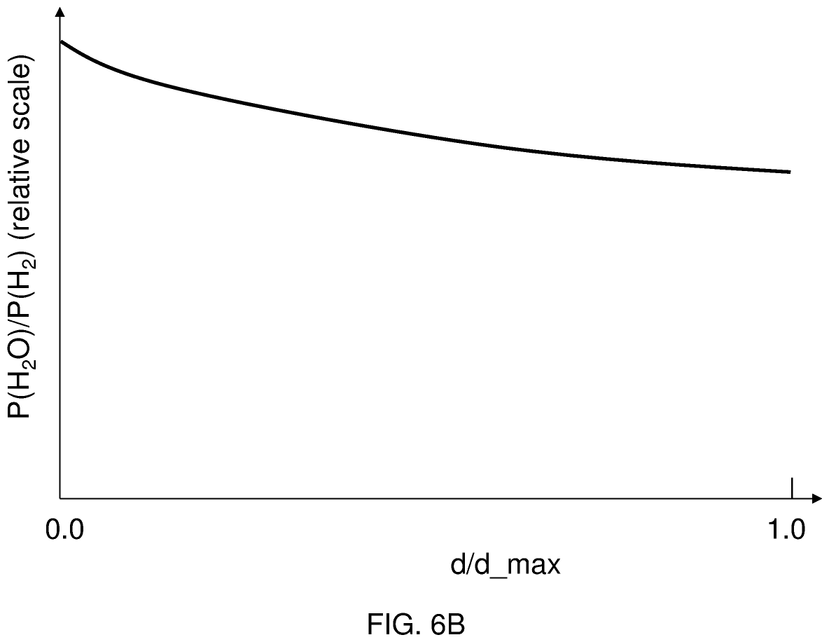

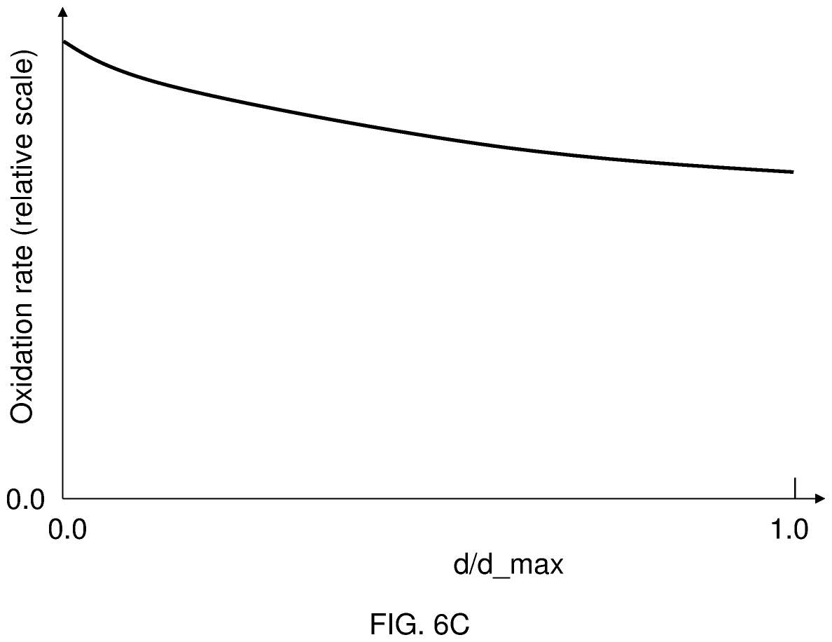

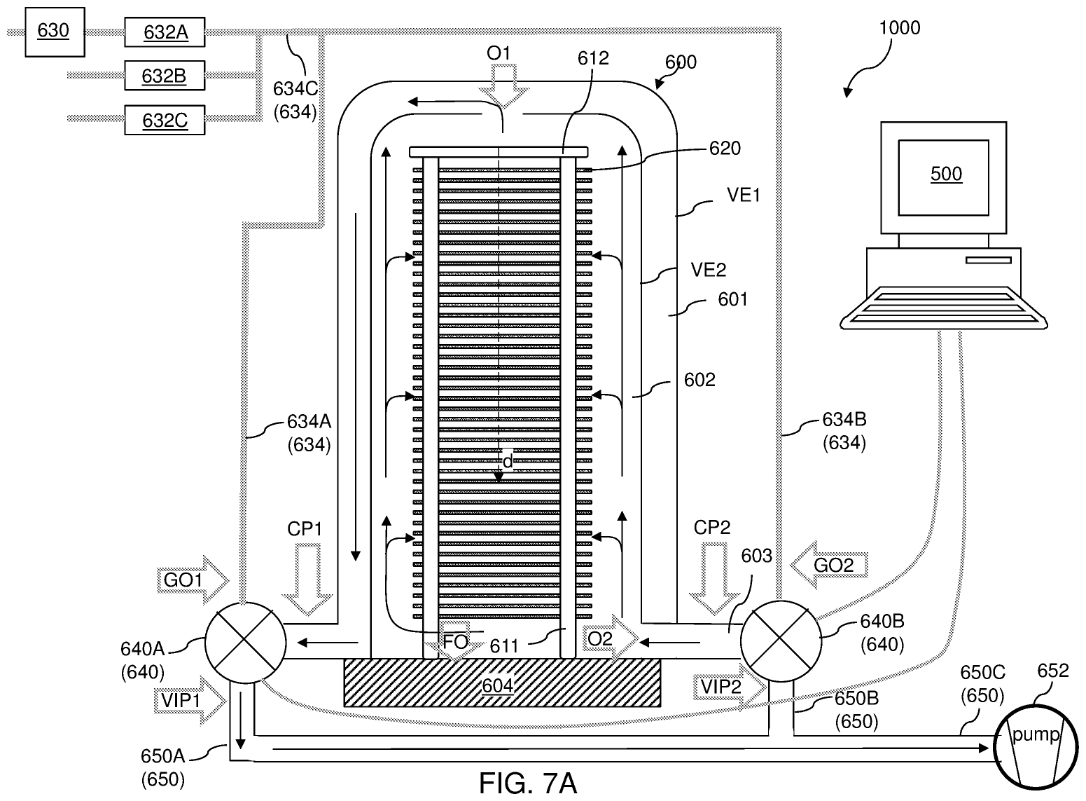

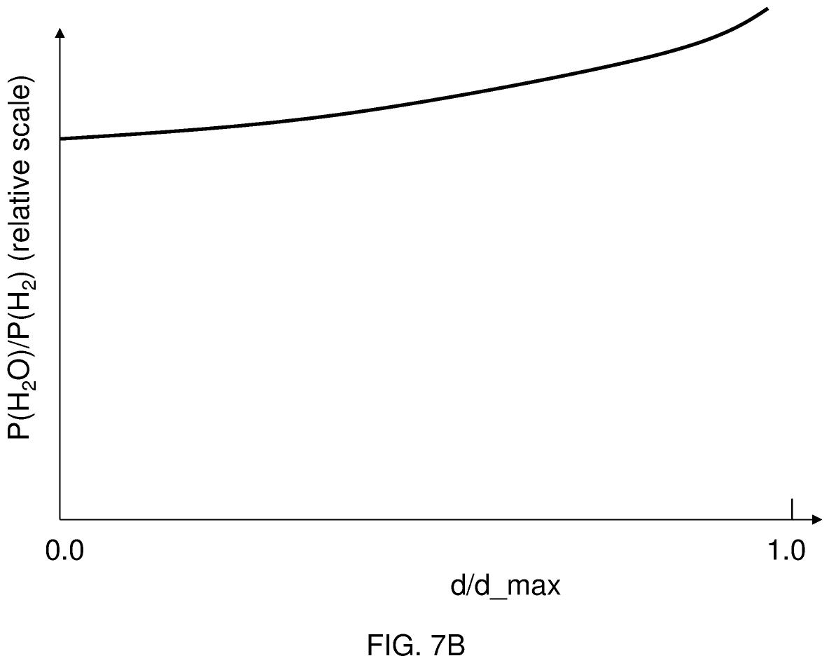

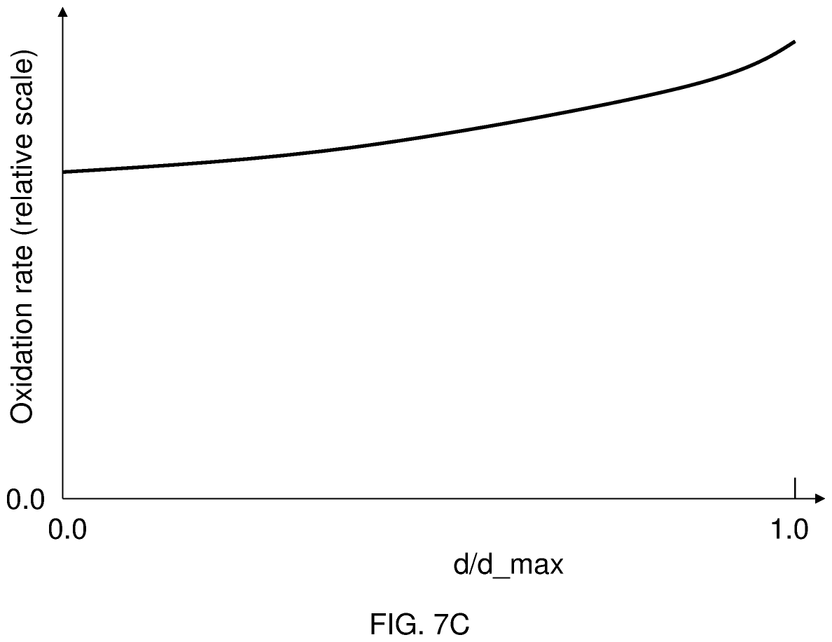

According to an aspect of the present disclosure, an apparatus that is configured to reverse the direction of a reactant gas at least once during a layer formation process is illustrated. The direction of the gas flow for a first processing step within the layer formation process is along a first direction, and the direction of the gas flow for a second processing step within the layer formation process is along a second direction that is the opposite of the first direction. The process may be an oxidation process, a nitridation process, or a deposition process such as a chemical vapor deposition process or an atomic layer deposition process. Thus, an oxide layer (e.g., silicon oxide), a nitride layer (e.g., silicon nitride), an oxynitride layer (e.g., silicon oxynitride), or a semiconductor layer (e.g., silicon) may be formed by oxidation, nitridation, oxidation and nitridation, or deposition. FIGS. 6A and 7A illustrate a dual reactant flow apparatus of an embodiment of the present disclosure. FIG. 6A illustrates the gas flow configuration during a first process step, and FIG. 7A illustrates the gas flow configuration during a second process step of the same layer formation process.

Referring collectively to FIGS. 6A and 7A, an apparatus 1000 of one embodiment of the present disclosure comprises a vacuum chamber 600 that is elongated along a first direction (such as a vertical direction) and enclosing a vacuum chamber having a first orifice (i.e., opening) O1 located at a first end (such as a top end) of the vacuum chamber, a second orifice (i.e., opening) O2 located proximate to a second end (such as a bottom end) of the vacuum chamber, and has a flange opening FO at the second end (such as a bottom end) of the vacuum chamber. The vacuum chamber 600 may contain at least one internal chamber portions, such as a first chamber portion 601 fluidly connected to the first orifice O1, a second chamber portion 602 fluidly connected to the first and the second orifices (O1, O2), and a third chamber portion 603 fluidly connected to the second orifice O2. In one embodiment, the first chamber portion 601 may be an outer chamber portion, the second chamber portion 602 may be an inner (e.g., central) chamber portion surrounded by the outer chamber portion 601, and the third chamber portion 603 may be a bottom chamber portion. The outer chamber portion 601 is located between the outer vacuum enclosure VE1 and the inner vacuum enclosure VE2. A first connection port CP1 is fluidly connected to the outer chamber portion 601. The inner chamber portion 602 is located inside the inner vacuum enclosure VE2. The inner vacuum enclosure VE2 includes the first orifice O1 and the second orifice O2. The third chamber portion 603 may be located in a connection tube or manifold which fluidly connects the second orifice O2 and the second connection port CP2 and extends through the outer vacuum enclosure VE1.

The apparatus 1000 also comprises a vacuum flange 604 located at or proximate to the flange opening FO and configured to provide a seal at the flange opening FO against the vacuum chamber 600. Further, the apparatus 1000 comprises a boat (611, 612) extending along the first direction and configured to hold wafers 620 thereupon. The boat may be located in the second chamber portion 602. For example, the boat (611, 612) may comprise a set of rails 611 with notches thereupon, and an end plate 612 that is proximal to the first orifice O1. The notches on the rails 611 may be configured to hold the wafers 620 (e.g., substrates 8 described above) with a uniform spacing along a direction that is parallel to or antiparallel to the direction of a gas flow within the elongated chamber 600. Optionally, a pedestal (not shown) may be provided between the boat (611, 612) and the vacuum flange 604.

The apparatus 1000 also comprises a gas distribution conduit (e.g., manifold or pipe) 634 containing a first and second gas flow switches (e.g., computer controlled valves) (640A, 640B) configured to control a flow rate of a reactant gas (e.g., oxidant gate) through the conduit 634. A set of mass flow controllers (632A, 632B, 632C) which control the flow of one or more reactant gases may be attached to a gas inlet portion 634C of the gas distribution conduit 634. The gas inlet portion 634C of the gas distribution conduit 634 is attached to two gas outlet portions (634A, 634B) of the gas distribution conduit 634. The two gas outlet portions (634A, 634B) of the gas distribution conduit 634 comprises a first gas outlet portion 634A having a first gas outlet GO1 at the exit end, and a second gas outlet portion 634B having a second gas outlet GO2 at the exit end. The first gas outlet GO1 and the second gas outlet GO2 are connected in parallel to the gas inlet portion 634 of the gas distribution conduit 634.

The apparatus 1000 also comprises a vacuum conduit 650 configured to pump out exhaust gas from the vacuum chamber 600. The vacuum conduit 650 comprises a common vacuum exhaust segment 650C that is connected to a vacuum pump 652, a first vacuum conduit segment 650A having a first vacuum inlet port VIP1 at one end and connected to the common vacuum exhaust segment 650C at another end, and a second vacuum conduit segment 650B having a second vacuum inlet portion VIP2 at one end and connected to the common vacuum exhaust segment 650C at another end.

According to an aspect of the present disclosure, the first gas flow switch 640A is connected to the first gas outlet GO1, the first vacuum inlet port VIP1, and a first connection port CP1 that is connected to the first orifice O1 by a first chamber portion 601 of the vacuum chamber 600. The second gas flow switch 640B is connected to the second gas outlet GO2, the second vacuum inlet port VIP2, and a second connected port CP2 connected to the second orifice O2 by the third chamber portion 603.

According to an aspect of the present disclosure, a process controller 500 may be provided, which is configured to control the first gas flow switch 640A and the second gas flow switch 640B to provide a gas flow in two configurations during different processing steps of a same process that is performed employing the apparatus 1000. In a first gas flow configuration illustrated in FIG. 6A, the reactant gas flows from the first gas outlet GO1, through the first gas flow switch 640A and the first connection port CP1, and the first chamber portion 601 toward the first orifice O1. In a second gas flow configuration illustrated in FIG. 7A, the reactant gas flows from the second gas outlet GO2, through the second gas flow switch 640B and the second connection port CP2, and the third chamber portion 603 toward the second orifice O2. The gas flow directions are illustrated by arrows in FIGS. 6A and 7A. In one embodiment, the process controller 500 is loaded with an automated program that switches the gas flow between the first gas flow configuration and the second gas flow configuration during processing. In one embodiment, the automated program is configured to provide the gas flow in the first gas flow configuration for a first duration that is in a range from ⅓ of a total duration of a gas flow time to ⅔ of the total duration of the gas flow time, and to provide the gas flow in the second gas flow configuration for a second duration of time that is a balance of the first duration relative to the total duration.

In one embodiment, the first gas flow switch 640A disconnects a first fluid flow path between the first vacuum inlet port VIP1 and the first connection port CP1 in the first gas flow configuration, and the second gas flow switch 640B connects a second fluid flow path between the second vacuum inlet port VIP2 and the second connection port in the first gas flow configuration. In one embodiment, the first gas flow switch 640A connects the first fluid flow path between the first vacuum inlet port VIP1 and the first connection port CP1 in the second gas flow configuration, and the second gas flow switch 640B disconnects the second fluid flow path between the second vacuum inlet port VIP2 and the second connection port in the second gas flow configuration.

In one embodiment, the second gas flow switch 640B disconnects a fluid flow path between the second gas outlet GO2 and the second connection port in the first gas flow configuration, and the first gas flow switch 640A disconnects a fluid flow path between the first gas outlet GO1 and the first connection port CP1 in the second gas flow configuration.

The apparatus 1000 of the embodiments of the present disclosure may be employed for various processes such as an oxidation process, a nitridation process, and/or a deposition process. In case the apparatus 1000 is employed for an oxidation process, the reactant gas comprises an oxidant gas such as H₂O, O₂, NO₂, and/or NO. For example, in case the oxidant comprises water vapor, then a water vapor generator 630 may be fluidly connected to the mass flow controller 632A. The other mass flow controllers (632B, 632C) may be connected to various gas containers (e.g., gas cylinders), such as hydrogen, deuterium, oxygen, nitrogen, etc. containers. In case the apparatus 1000 is employed for a nitridation process, the reactant gas comprises a nitridation agent gas such as NH 3. In case the apparatus 1000 is employed for a deposition process (such as a chemical vapor deposition process or an atomic layer deposition process), the reactant gas comprises a precursor gas that deposits a semiconductor element or a metal upon decomposition. For example, silicon, a silicon-germanium alloy, germanium, a metallic nitride material (such as TiN, TaN, WN, or MoN), or a metal may be deposited.

In one embodiment, the process controller 500 can be configured to control the first gas flow switch 640A and the second gas flow switch 640B to provide a gas flow in a configuration selected from a first gas flow configuration in which the reactant gas flows within the vacuum chamber along a direction from the first orifice O1 toward the second orifice O2 (as illustrated in FIG. 6A), and a second gas flow configuration in which the reactant gas flows within the vacuum chamber along a direction from the second orifice O2 toward the first orifice O1 (as illustrated in FIG. 7A).

Generally, the dual flow configuration of the apparatus 1000 may be employed advantageously to provide enhanced wafer-to-wafer layer thickness uniformity within each batch of wafers processed within the apparatus 1000 for any of oxidation processes, nitridation processes, and deposition processes. In case the process performed in the apparatus 1000 comprises an oxidation process, the apparatus of the embodiments of the present disclosure can provide the benefit of improved wafer-to-wafer silicon oxide layer thickness uniformity through control of the partial pressure of an oxidant gas.

FIG. 6B is a graph illustrating a ratio of a water vapor partial pressure to a hydrogen partial pressure as a function of a downward vertical distance within a boat (611, 612) located in the exemplary apparatus 1000 during the first processing step in case an oxidation process is performed according to an embodiment of the present disclosure. The distance d is measured downward from the endplate 612 of the boat (611, 612) that contains the wafers 620. The maximum distance d_max is the length of the boat (611, 612) along the vertical direction. During the first processing step, the gas flow in the second (e.g., inner) chamber portion 602 is along the direction from the first orifice O1 to the second orifice O2 (e.g., downward), and the partial pressure of the oxidant gas (such as water vapor) decreases with the distance d due to outgassing of non-oxidant gas (such as hydrogen) from the wafers 620. Thus, the oxidation rate during the first processing step decreases with the distance d as illustrated in FIG. 6C.

FIG. 7B is a graph illustrating a ratio of a water vapor partial pressure to a hydrogen partial pressure as a function of a vertical distance downward within a boat (611, 612) in in the exemplary apparatus 1000 during the second processing step in case an oxidation process is performed according to an embodiment of the present disclosure. During the second processing step, the gas flow in the second chamber portion 602 is along the direction from the second orifice O2 to the first orifice O1 (e.g., upward), and the partial pressure of the oxidant gas (such as water vapor) increases with the distance d due to outgassing of non-oxidant gases (such as hydrogen) from the wafers 620. Thus, the oxidation rate during the second processing step increases with the downward distance d as illustrated in FIG. 7C. Thus, the second processing step balances the first processing step.

By employing a combination of the first processing step and the second processing step, an oxidation process that is performed employing the apparatus 1000 of the present disclosure can form the sacrificial semiconductor oxide portions (1481, 1482, 1483) with enhanced wafer-to-wafer thickness uniformity. Specifically, the variation in the thickness of the sacrificial semiconductor oxide portions (1481, 1482, 1483) along the downward vertical distance d within the vacuum chamber 600 can be reduced. In one embodiment, the ratio of the duration of the first processing step that is performed in the first flow configuration of FIG. 6A to the duration of the second processing step that is performed in the second flow configuration of FIG. 7A may be in a range from 0.5 to 2.0, and/or from ⅔ to 1.5, and/or from 0.8 to 1.25, and/or about 1.0.

According to an embodiment of the present disclosure, a method of operating the apparatus 1000 includes the following steps. Wafers 620 can be loaded onto the boat (611, 612). A combination of the boat (611, 612) and the wafers 620 can be loaded into the vacuum chamber 600, and the vacuum flange 604 can be sealed against the vacuum chamber 600. At least one material portion can be grown on each of the wafers 620 by flowing a reactant gas within vacuum chamber 600 in two direction in two processing steps. The reactant gas flows along a direction from the first orifice O1 toward the second orifice O2 during a first processing step of the two processing steps. The reactant gas flows along a direction from the second orifice O2 toward the first orifice O1 during a second processing step of the two processing steps. The second processing step is performed after or prior to the first processing step. While two processing steps are described, three or more processing steps may be performed in which the reactant gas sequentially flows in opposite directions.

In one embodiment, the apparatus 1000 comprises a gas distribution conduit 634 containing switches (640A, 640B) configured to control a flow rate of the reactant gas and having a first gas outlet GO1 and a second gas outlet GO2 that are connected in parallel. The reactant gas flows from the first gas outlet GO1, through the first orifice O1 and then through the vacuum chamber 600 and then through the second orifice O2 during the first processing step. The reactant gas flows from the second gas outlet GO2, through the second orifice O2 and then through the vacuum chamber and then through the first orifice O1 during the second processing step.

In one embodiment, the apparatus 1000 comprises a vacuum pump 652 connected to a vacuum conduit 650 having a first vacuum inlet port VIP1 and a second vacuum inlet port VIP2. The reactant gas is pumped out from the vacuum chamber 600 through the second vacuum inlet port VIP2 during the first processing step. The reactant gas is pumped out from the vacuum chamber 600 through the first vacuum inlet port VIP1 during the second processing step.

In one embodiment, the apparatus 1000 comprises a first gas flow switch 640A connected to the first gas outlet GO1, the first vacuum inlet port VIP1, and a first connection port CP1 connected to the first orifice O1; and a second gas flow switch 640B connected to the second gas outlet GO2, the second vacuum inlet port VIP2, and a second connected port CP2 connected to the second orifice O2. The reactant gas flows from the first gas outlet GO1, through the first gas flow switch 640A and the first connection port CP1, and toward the first orifice O1 during the first processing step. The reactant gas flows from the second gas outlet GO2, through the second gas flow switch 640B and the second connection port, and toward the second orifice O2 during the second processing step.

In one embodiment, the first processing step is performed for a first duration; the second processing step is performed for a second duration; and a fraction of the first duration relative to a sum of the first duration and the second duration is in a range from ⅓ to ⅔.

In one embodiment, the reactant gas comprises an oxidant gas, such as water vapor. In one embodiment, the reactant gas comprises ammonia gas used for nitridation. In one embodiment, the reactant gas comprises a precursor gas (e.g., silane, etc.) that deposits a semiconductor element or a metal upon decomposition.

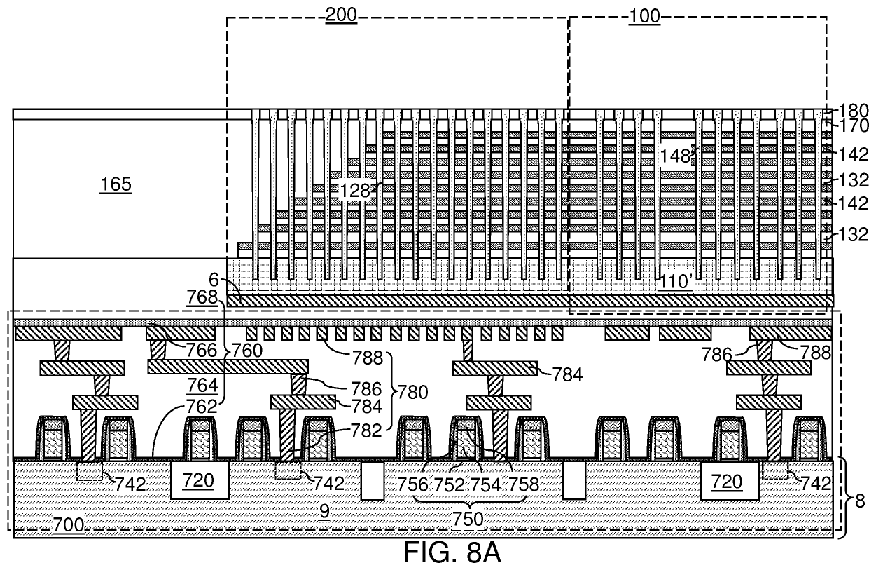

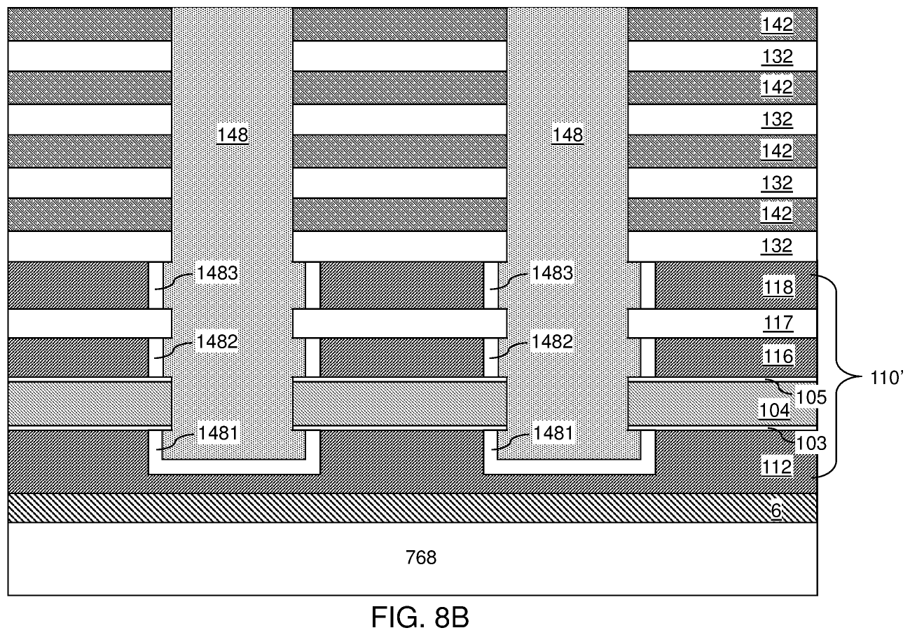

Referring to FIGS. 8A and 8B, sacrificial first-tier opening fill portions (148, 128) may be formed in the various first-tier openings (149, 129). For example, a sacrificial first-tier fill material is concurrently deposited in each of the first-tier openings (149, 129). The sacrificial first-tier fill material includes a material that may be subsequently removed selective to the materials of the first insulating layers 132 and the first sacrificial material layers 142.

In one embodiment, the sacrificial first-tier fill material may include a semiconductor material such as silicon (e.g., amorphous or polysilicon), a silicon-germanium alloy, germanium, a III-V compound semiconductor material, or a combination thereof. The sacrificial first-tier fill material may be formed by a non-conformal deposition or a conformal deposition method.

In another embodiment, the sacrificial first-tier fill material may a carbon-containing material (such as amorphous carbon or diamond-like carbon) that may be subsequently removed by ashing, or a silicon-based polymer that may be subsequently removed selective to the materials of the first-tier alternating stack (132, 142).

Portions of the deposited sacrificial material may be removed from above the topmost layer of the first-tier alternating stack (132, 142), such as from above the inter-tier dielectric layer 180. For example, the sacrificial first-tier fill material may be recessed to a top surface of the inter-tier dielectric layer 180 using a planarization process. The planarization process may include a recess etch, chemical mechanical planarization (CMP), or a combination thereof. The top surface of the inter-tier dielectric layer 180 may be used as an etch stop layer or a planarization stop layer.

Remaining portions of the sacrificial first-tier fill material comprise sacrificial first-tier opening fill portions (148, 128). Specifically, each remaining portion of the sacrificial material in a first-tier memory opening 149 constitutes a sacrificial first-tier memory opening fill portion 148. Each remaining portion of the sacrificial material in a first-tier support opening 129 constitutes a sacrificial first-tier support opening fill portion 128. The various sacrificial first-tier opening fill portions (148, 128) are concurrently formed, i.e., during a same set of processes including the deposition process that deposits the sacrificial first-tier fill material and the planarization process that removes the first-tier deposition process from above the first-tier alternating stack (132, 142) (such as from above the top surface of the inter-tier dielectric layer 180). The top surfaces of the sacrificial first-tier opening fill portions (148, 128) may be coplanar with the top surface of the inter-tier dielectric layer 180. Each of the sacrificial first-tier opening fill portions (148, 128) may, or may not, include cavities therein.

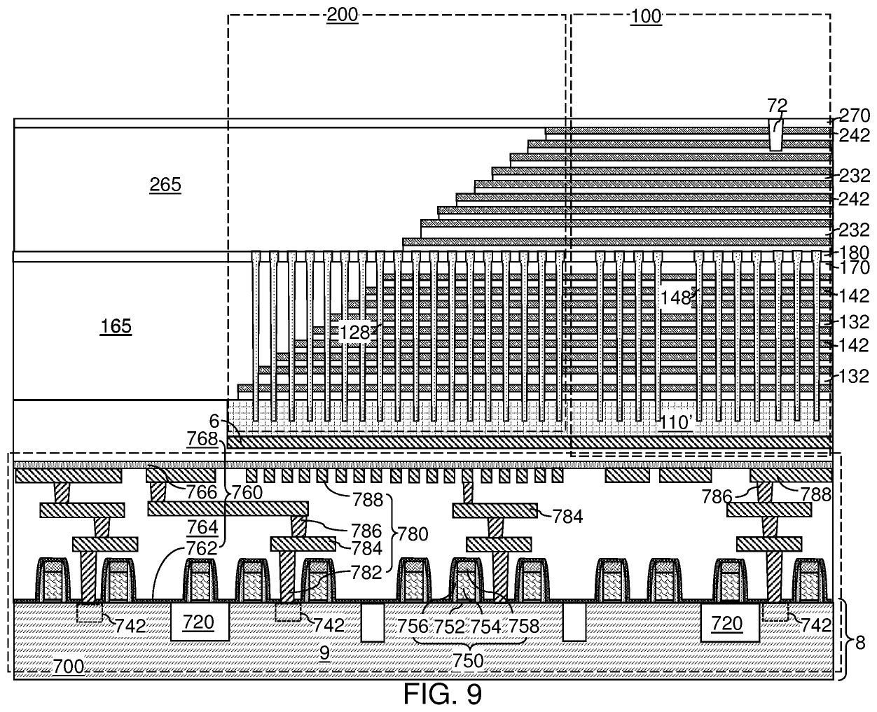

Referring to FIG. 9, a second-tier structure may be formed over the first-tier structure (132, 142, 170, 148). The second-tier structure may include an additional alternating stack of insulating layers and spacer material layers, which may be sacrificial material layers. For example, a second-tier alternating stack (232, 242) of material layers may be subsequently formed on the top surface of the first-tier alternating stack (132, 142). The second-tier alternating stack (232, 242) includes an alternating plurality of third material layers and fourth material layers. Each third material layer may include a third material, and each fourth material layer may include a fourth material that is different from the third material. In one embodiment, the third material may be the same as the first material of the first insulating layer 132, and the fourth material may be the same as the second material of the first sacrificial material layers 142.

In one embodiment, the third material layers may be second insulating layers 232 and the fourth material layers may be second spacer material layers that provide vertical spacing between each vertically neighboring pair of the second insulating layers 232. In one embodiment, the third material layers and the fourth material layers may be second insulating layers 232 and second sacrificial material layers 242, respectively. The third material of the second insulating layers 232 may be at least one insulating material. The fourth material of the second sacrificial material layers 242 may be a sacrificial material that may be removed selective to the third material of the second insulating layers 232. The second sacrificial material layers 242 may comprise an insulating material, a semiconductor material, or a conductive material. The fourth material of the second sacrificial material layers 242 may be subsequently replaced with electrically conductive electrodes which may function, for example, as control gate electrodes of a vertical NAND device.

In one embodiment, each second insulating layer 232 may include a second insulating material, and each second sacrificial material layer 242 may include a second sacrificial material. In this case, the second-tier alternating stack (232, 242) may include an alternating plurality of second insulating layers 232 and second sacrificial material layers 242. The third material of the second insulating layers 232 may be deposited, for example, by chemical vapor deposition (CVD). The fourth material of the second sacrificial material layers 242 may be formed, for example, CVD or atomic layer deposition (ALD).

The third material of the second insulating layers 232 may be at least one insulating material. Insulating materials that may be used for the second insulating layers 232 may be any material that may be used for the first insulating layers 132. The fourth material of the second sacrificial material layers 242 is a sacrificial material that may be removed selective to the third material of the second insulating layers 232. Sacrificial materials that may be used for the second sacrificial material layers 242 may be any material that may be used for the first sacrificial material layers 142. In one embodiment, the second insulating material may be the same as the first insulating material, and the second sacrificial material may be the same as the first sacrificial material.

The thicknesses of the second insulating layers 232 and the second sacrificial material layers 242 may be in a range from 20 nm to 50 nm, although lesser and greater thicknesses may be used for each second insulating layer 232 and for each second sacrificial material layer 242. The number of repetitions of the pairs of a second insulating layer 232 and a second sacrificial material layer 242 may be in a range from 2 to 1,024, and typically from 8 to 256, although a greater number of repetitions may also be used. In one embodiment, each second sacrificial material layer 242 in the second-tier alternating stack (232, 242) may have a uniform thickness that is substantially invariant within each respective second sacrificial material layer 242.

Second stepped surfaces in the second stepped area may be formed in the staircase region 200 using a same set of processing steps as the processing steps used to form the first stepped surfaces in the first stepped area with suitable adjustment to the pattern of at least one masking layer. A second retro-stepped dielectric material portion 265 may be formed over the second stepped surfaces in the staircase region 200.

A second insulating cap layer 270 may be subsequently formed over the second-tier alternating stack (232, 242). The second insulating cap layer 270 includes a dielectric material that is different from the material of the second sacrificial material layers 242. In one embodiment, the second insulating cap layer 270 may include silicon oxide. In one embodiment, the first and second sacrificial material layers (142, 242) may comprise silicon nitride.

Generally speaking, at least one alternating stack of insulating layers (132, 232) and spacer material layers (such as sacrificial material layers (142, 242)) may be formed over the in-process source-level material layers 110′, and at least one retro-stepped dielectric material portion (165, 265) may be formed over the staircase regions on the at least one alternating stack (132, 142, 232, 242).

Optionally, drain-select-level isolation structures 72 may be formed through a subset of layers in an upper portion of the second-tier alternating stack (232, 242). The second sacrificial material layers 242 that are cut by the drain-select-level isolation structures 72 correspond to the levels in which drain-select-level electrically conductive layers are subsequently formed. The drain-select-level isolation structures 72 include a dielectric material such as silicon oxide. The drain-select-level isolation structures 72 may laterally extend along a first horizontal direction hd1, and may be laterally spaced apart along a second horizontal direction hd2 that is perpendicular to the first horizontal direction hd1. The combination of the second-tier alternating stack (232, 242), the second retro-stepped dielectric material portion 265, the second insulating cap layer 270, and the optional drain-select-level isolation structures 72 collectively constitute a second-tier structure (232, 242, 265, 270, 72).

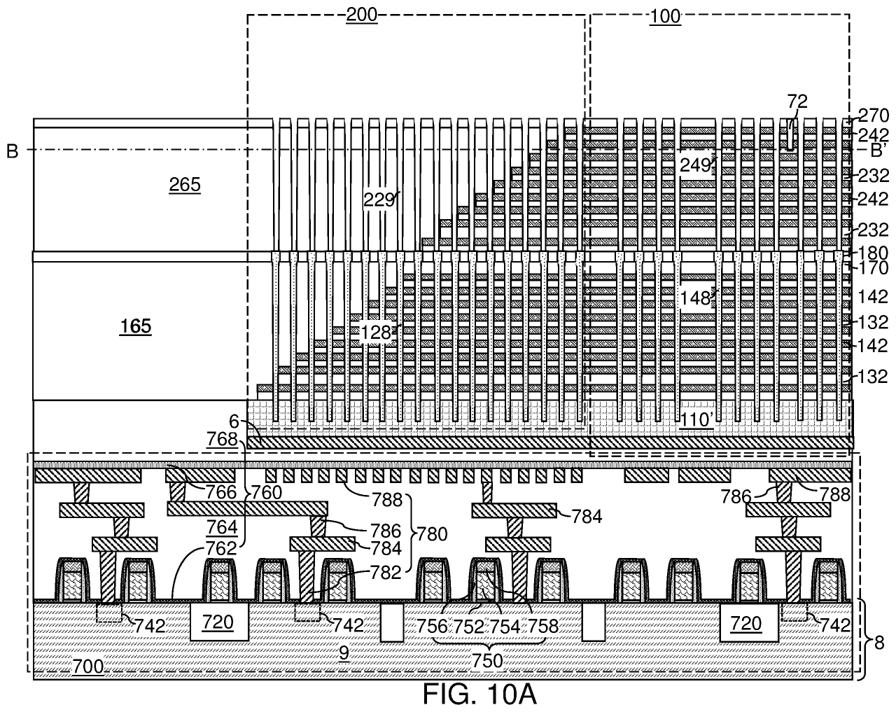

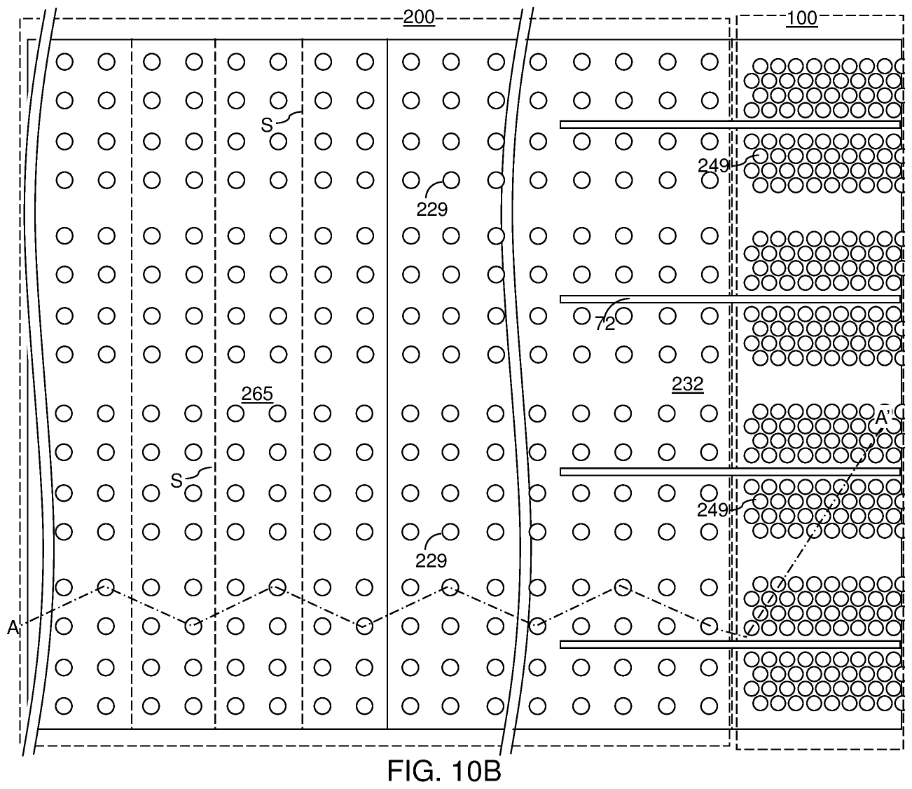

Referring to FIGS. 10A and 10B, various second-tier openings (249, 229) may be formed through the second-tier structure (232, 242, 265, 270, 72). A photoresist layer (not shown) may be applied over the second insulating cap layer 270, and may be lithographically patterned to form various openings therethrough. The pattern of the openings may be the same as the pattern of the various first-tier openings (149, 129), which is the same as the sacrificial first-tier opening fill portions (148, 128). Thus, the lithographic mask used to pattern the first-tier openings (149, 129) may be used to pattern the photoresist layer.

The pattern of openings in the photoresist layer may be transferred through the second-tier structure (232, 242, 265, 270, 72) by a second anisotropic etch process to form various second-tier openings (249, 229) concurrently, i.e., during the second anisotropic etch process. The various second-tier openings (249, 229) may include second-tier memory openings 249 and second-tier support openings 229.

The second-tier memory openings 249 are formed directly on a top surface of a respective one of the sacrificial first-tier memory opening fill portions 148. The second-tier support openings 229 are formed directly on a top surface of a respective one of the sacrificial first-tier support opening fill portions 128. Further, each second-tier support openings 229 may be formed through a horizontal surface within the second stepped surfaces, which include the interfacial surfaces between the second-tier alternating stack (232, 242) and the second retro-stepped dielectric material portion 265. Locations of steps S in the first-tier alternating stack (132, 142) and the second-tier alternating stack (232, 242) are illustrated as dotted lines in FIG. 7B.

The second anisotropic etch process may include an etch step in which the materials of the second-tier alternating stack (232, 242) are etched concurrently with the material of the second retro-stepped dielectric material portion 265. The chemistry of the etch step may alternate to optimize etching of the materials in the second-tier alternating stack (232, 242) while providing a comparable average etch rate to the material of the second retro-stepped dielectric material portion 265. The second anisotropic etch process may use, for example, a series of reactive ion etch processes or a single reaction etch process (e.g., CF₄/O₂/Ar etch). The sidewalls of the various second-tier openings (249, 229) may be substantially vertical, or may be tapered. A bottom periphery of each second-tier opening (249, 229) may be laterally offset, and/or may be located entirely within, a periphery of a top surface of an underlying sacrificial first-tier opening fill portion (148, 128). The photoresist layer may be subsequently removed, for example, by ashing.

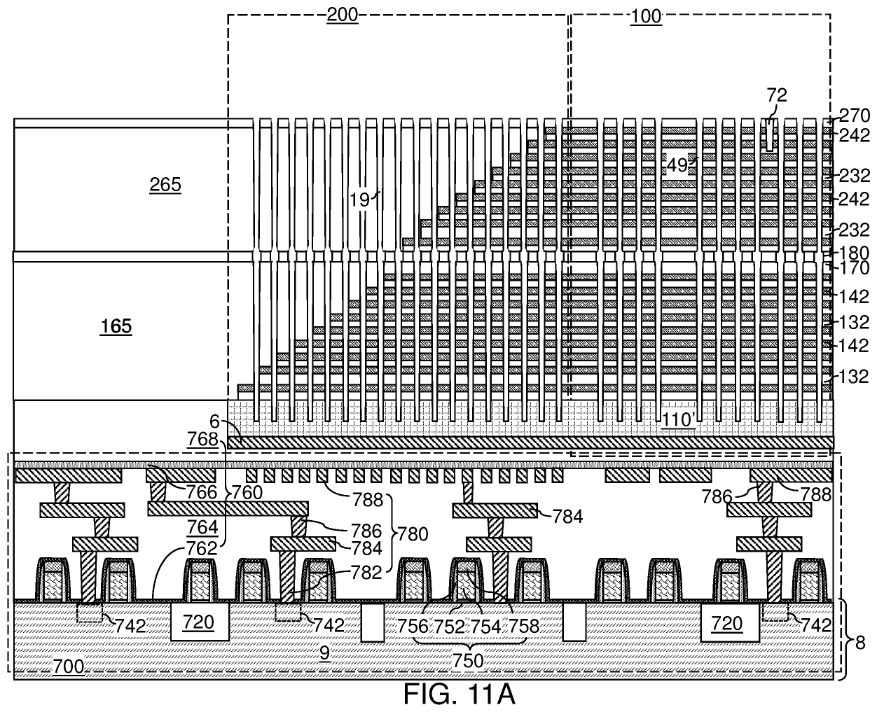

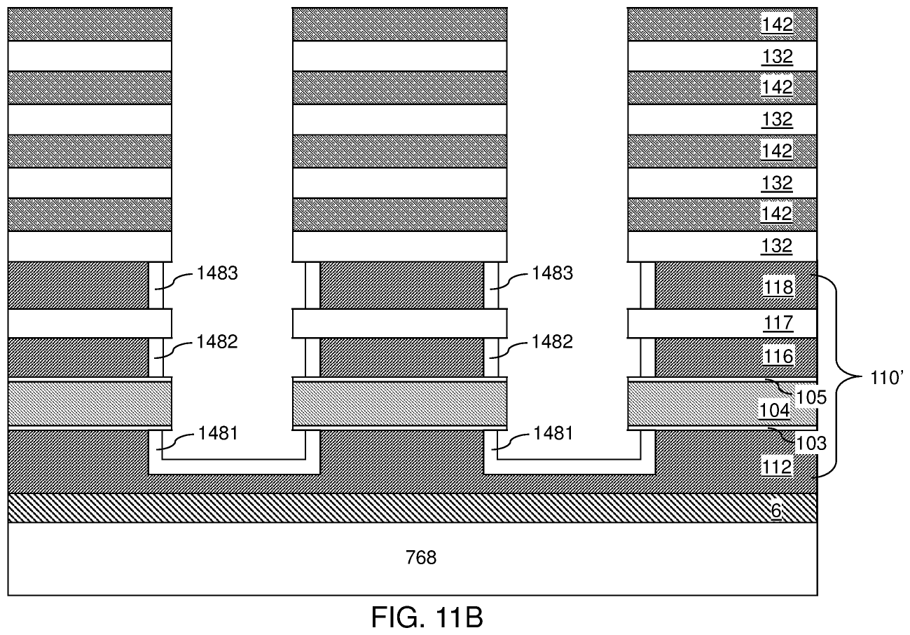

Referring to FIGS. 11A and 11B, the sacrificial first-tier fill material of the sacrificial first-tier opening fill portions (148, 128) may be removed using an etch process that etches the sacrificial first-tier fill material selective to the materials of the first and second insulating layers (132, 232), the first and second sacrificial material layers (142, 242), the first and second insulating cap layers (170, 270), and the inter-tier dielectric layer 180. For example, if the sacrificial first-tier opening fill portions (148, 128) comprise a semiconductor material such as amorphous silicon or polysilicon, a wet etch process using hot trimethyl-2 hydroxyethyl ammonium hydroxide (“hot TMY”) or tetramethyl ammonium hydroxide (TMAH) may be performed to remove the sacrificial first-tier opening fill portions (148, 128) selective to the materials of the insulating layers (132, 232), the sacrificial material layers (142, 242), and the sacrificial semiconductor oxide portions (1481, 1482, 1483). The sacrificial semiconductor oxide portions (1481, 1482, 1483) protect the respective silicon layers (112, 116, 118) from being etched. Since the sacrificial semiconductor oxide portions (1481, 1482, 1483) have a sufficient thickness irrespective of whether they are located on a substrate 8 that was located at the top or the bottom of the boat (611, 612) in the dual flow oxidation apparatus 1000, the sacrificial semiconductor oxide portions (1481, 1482, 1483) have a low likelihood of pinholes. Therefore, the likelihood of etching the silicon layers (112, 116, 118) during this etching step is reduced or eliminated. Alternatively, if the sacrificial first-tier opening fill portions (148, 128) comprise a carbon-based material such as amorphous carbon or diamond-like carbon (DLC), an ashing process may be employed to remove sacrificial first-tier opening fill portions (148, 128) selective to the materials of the insulating layers (132, 232), the sacrificial material layers (142, 242), and the sacrificial semiconductor oxide portions (1481, 1482, 1483).

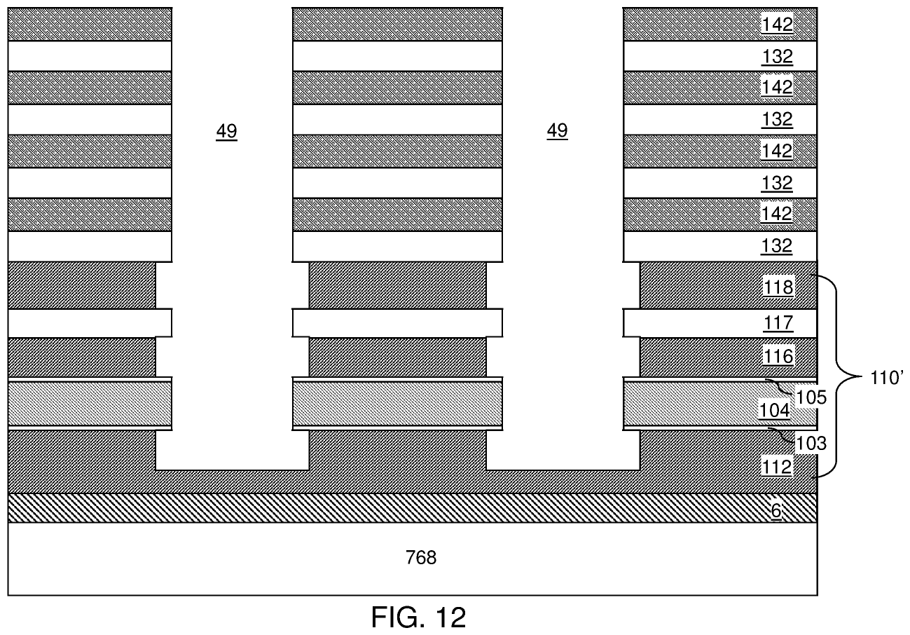

Referring to FIG. 12, the sacrificial semiconductor oxide portions (1481, 1482, 1483) may be removed selective to the materials of the upper source-level semiconductor layer 116, the lower source-level semiconductor layer 112, and the source-select-level conductive layer 118. For example, a wet etch process employing dilute hydrofluoric acid may be employed to remove the sacrificial semiconductor oxide portions (1481, 1482, 1483).

A memory opening 49, which is also referred to as an inter-tier memory opening 49, is formed in each combination of a second-tier memory openings 249 and a volume from which a sacrificial first-tier memory opening fill portion 148 and a set of sacrificial semiconductor oxide portions (1481, 1482, 1483) are removed. A support opening 19, which is also referred to as an inter-tier support opening 19, is formed in each combination of a second-tier support openings 229 and a volume from which a sacrificial first-tier support opening fill portion 128 and a set of sacrificial semiconductor oxide portions (1481, 1482, 1483) are removed.

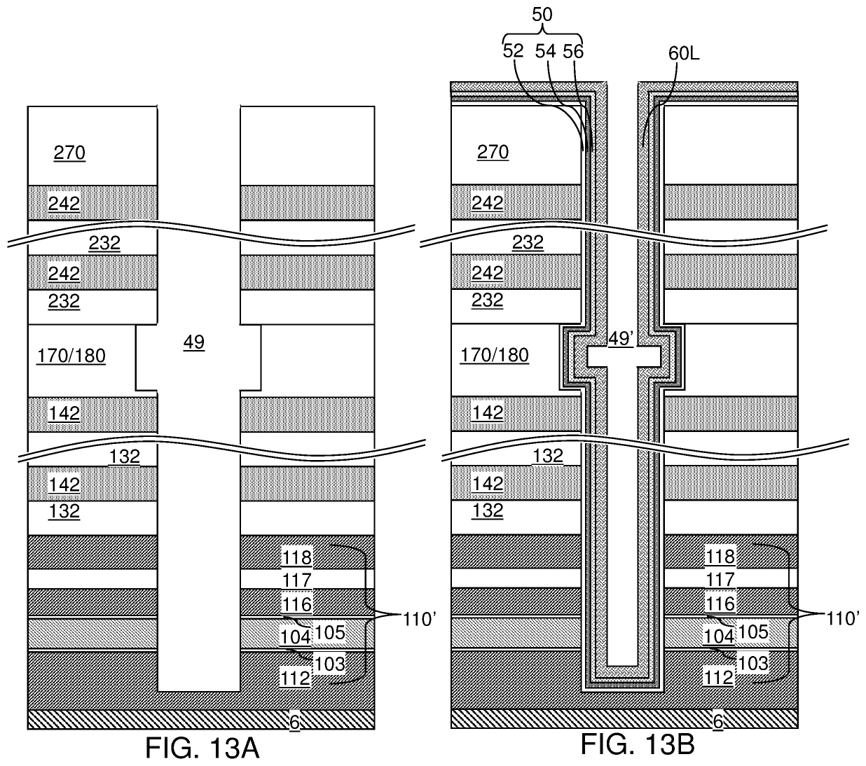

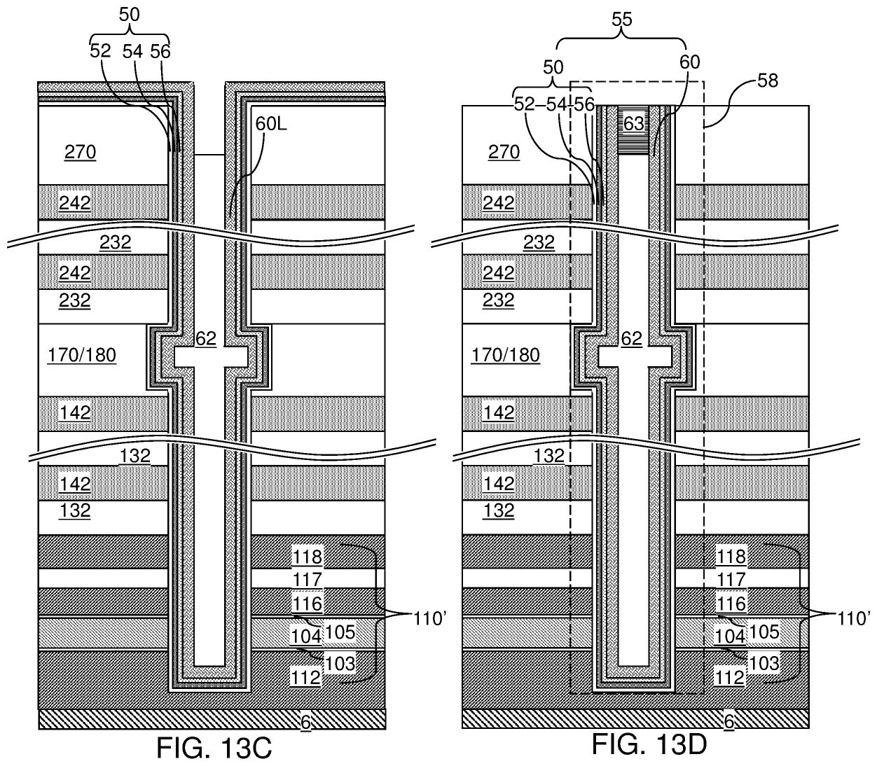

FIGS. 13A-13D provide sequential cross-sectional views of a memory opening 49 during formation of a memory opening fill structure. The same structural change occurs in each of the memory openings 49 and the support openings 19. It is understood that lateral recessing of sidewalls of the upper source-level semiconductor layer 116, the lower source-level semiconductor layer 112, and the source-select-level conductive layer 118 (illustrated in FIG. 12) may be present at the processing steps of FIGS. 13A-13D, although such lateral recessing is not illustrated in detail in FIGS. 13A-13D.

Referring to FIG. 13A, a memory opening 49 in the first exemplary device structure of FIG. 12 is illustrated. The memory opening 49 extends through the first-tier structure and the second-tier structure.

Referring to FIG. 13B, a stack of layers including a blocking dielectric layer 52, a charge storage layer 54, a tunneling dielectric layer 56, and a semiconductor channel material layer 60L may be sequentially deposited in the memory openings 49. The blocking dielectric layer 52 may include a single dielectric material layer or a stack of a plurality of dielectric material layers. In one embodiment, the blocking dielectric layer may include a dielectric metal oxide layer consisting essentially of a dielectric metal oxide. As used herein, a dielectric metal oxide refers to a dielectric material that includes at least one metallic element and at least oxygen. The dielectric metal oxide may consist essentially of the at least one metallic element and oxygen, or may consist essentially of the at least one metallic element, oxygen, and at least one non-metallic element such as nitrogen. In one embodiment, the blocking dielectric layer 52 may include a dielectric metal oxide having a dielectric constant greater than 7.9, i.e., having a dielectric constant greater than the dielectric constant of silicon nitride. The thickness of the dielectric metal oxide layer may be in a range from 1 nm to 20 nm, although lesser and greater thicknesses may also be used. The dielectric metal oxide layer may subsequently function as a dielectric material portion that blocks leakage of stored electrical charges to control gate electrodes. In one embodiment, the blocking dielectric layer 52 includes aluminum oxide. Alternatively or additionally, the blocking dielectric layer 52 may include a dielectric semiconductor compound such as silicon oxide, silicon oxynitride, silicon nitride, or a combination thereof.

Subsequently, the charge storage layer 54 may be formed. In one embodiment, the charge storage layer 54 may be a continuous layer or patterned discrete portions of a charge trapping material including a dielectric charge trapping material, which may be, for example, silicon nitride. Alternatively, the charge storage layer 54 may include a continuous layer or patterned discrete portions of a conductive material such as doped polysilicon or a metallic material that is patterned into multiple electrically isolated portions (e.g., floating gates), for example, by being formed within lateral recesses into sacrificial material layers (142, 242). In one embodiment, the charge storage layer 54 includes a silicon nitride layer. In one embodiment, the sacrificial material layers (142, 242) and the insulating layers (132, 232) may have vertically coincident sidewalls, and the charge storage layer 54 may be formed as a single continuous layer. Alternatively, the sacrificial material layers (142, 242) may be laterally recessed with respect to the sidewalls of the insulating layers (132, 232), and a combination of a deposition process and an anisotropic etch process may be used to form the charge storage layer 54 as a plurality of memory material portions that are vertically spaced apart. The thickness of the charge storage layer 54 may be in a range from 2 nm to 20 nm, although lesser and greater thicknesses may also be used.

The tunneling dielectric layer 56 includes a dielectric material through which charge tunneling may be performed under suitable electrical bias conditions. The charge tunneling may be performed through hot-carrier injection or by Fowler-Nordheim tunneling induced charge transfer depending on the mode of operation of the monolithic three-dimensional NAND string memory device to be formed. The tunneling dielectric layer 56 may include silicon oxide, silicon nitride, silicon oxynitride, dielectric metal oxides (such as aluminum oxide and hafnium oxide), dielectric metal oxynitride, dielectric metal silicates, alloys thereof, and/or combinations thereof. In one embodiment, the tunneling dielectric layer 56 may include a stack of a first silicon oxide layer, a silicon oxynitride layer, and a second silicon oxide layer, which is commonly known as an ONO stack. In one embodiment, the tunneling dielectric layer 56 may include a silicon oxide layer that is substantially free of carbon or a silicon oxynitride layer that is substantially free of carbon. The thickness of the tunneling dielectric layer 56 may be in a range from 2 nm to 20 nm, although lesser and greater thicknesses may also be used. The stack of the blocking dielectric layer 52, the charge storage layer 54, and the tunneling dielectric layer 56 constitutes a memory film 50 that stores memory bits.

The semiconductor channel material layer 60L includes a p-doped semiconductor material such as at least one elemental semiconductor material, at least one III-V compound semiconductor material, at least one II-VI compound semiconductor material, at least one organic semiconductor material, or other semiconductor materials known in the art. In one embodiment, the semiconductor channel material layer 60L may having a uniform doping. In one embodiment, the semiconductor channel material layer 60L has a p-type doping in which p-type dopants (such as boron atoms) are present at an atomic concentration in a range from 1.0×10¹²/cm³ to 1.0×10¹⁸/cm³, such as from 1.0×10¹⁴/cm³ to 1.0×10¹⁷/cm³. In one embodiment, the semiconductor channel material layer 60L includes, and/or consists essentially of, boron-doped amorphous silicon or boron-doped polysilicon. In another embodiment, the semiconductor channel material layer 60L has an n-type doping in which n-type dopants (such as phosphor atoms or arsenic atoms) are present at an atomic concentration in a range from 1.0×10¹²/cm³ to 1.0×10¹⁸/cm³, such as from 1.0×10¹⁴/cm³ to 1.0×10¹⁷/cm³. The semiconductor channel material layer 60L may be formed by a conformal deposition method such as low pressure chemical vapor deposition (LPCVD). The thickness of the semiconductor channel material layer 60L may be in a range from 2 nm to 10 nm, although lesser and greater thicknesses may also be used. A cavity 49′ is formed in the volume of each memory opening 49 that is not filled with the deposited material layers (52, 54, 56, 60L).

Referring to FIG. 13C, in case the cavity 49′ in each memory opening is not completely filled by the semiconductor channel material layer 60L, a dielectric core layer may be deposited in the cavity 49′ to fill any remaining portion of the cavity 49′ within each memory opening. The dielectric core layer includes a dielectric material such as silicon oxide or organosilicate glass. The dielectric core layer may be deposited by a conformal deposition method such as low pressure chemical vapor deposition (LPCVD), or by a self-planarizing deposition process such as spin coating. The horizontal portion of the dielectric core layer overlying the second insulating cap layer 270 may be removed, for example, by a recess etch. The recess etch continues until top surfaces of the remaining portions of the dielectric core layer are recessed to a height between the top surface of the second insulating cap layer 270 and the bottom surface of the second insulating cap layer 270. Each remaining portion of the dielectric core layer constitutes a dielectric core 62.

Referring to FIG. 13D, a doped semiconductor material having a doping of a second conductivity type may be deposited in cavities overlying the dielectric cores 62. The second conductivity type is the opposite of the first conductivity type. For example, if the first conductivity type is p-type, the second conductivity type is n-type, and vice versa. Portions of the deposited doped semiconductor material, the semiconductor channel material layer 60L, the tunneling dielectric layer 56, the charge storage layer 54, and the blocking dielectric layer 52 that overlie the horizontal plane including the top surface of the second insulating cap layer 270 may be removed by a planarization process such as a chemical mechanical planarization (CMP) process.

Each remaining portion of the doped semiconductor material of the second conductivity type constitutes a drain region 63. The dopant concentration in the drain regions 63 may be in a range from 5.0×10¹⁹/cm³ to 2.0×10²¹/cm³, although lesser and greater dopant concentrations may also be used. The doped semiconductor material may be, for example, doped polysilicon.

Each remaining portion of the semiconductor channel material layer 60L constitutes a vertical semiconductor channel 60 through which electrical current may flow when a vertical NAND device including the vertical semiconductor channel 60 is turned on. A tunneling dielectric layer 56 is surrounded by a charge storage layer 54, and laterally surrounds a vertical semiconductor channel 60. Each adjoining set of a blocking dielectric layer 52, a charge storage layer 54, and a tunneling dielectric layer 56 collectively constitute a memory film 50, which may store electrical charges with a macroscopic retention time. In some embodiments, a blocking dielectric layer 52 may not be present in the memory film 50 at this step, and a blocking dielectric layer may be subsequently formed after formation of backside recesses. As used herein, a macroscopic retention time refers to a retention time suitable for operation of a memory device as a permanent memory device such as a retention time in excess of 24 hours.

Each combination of a memory film 50 and a vertical semiconductor channel 60 within a memory opening 49 constitutes a memory stack structure 55. The memory stack structure 55 is a combination of a vertical semiconductor channel 60, a tunneling dielectric layer 56, a plurality of memory elements comprising portions of the charge storage layer 54, and an optional blocking dielectric layer 52. Each combination of a memory stack structure 55, a dielectric core 62, and a drain region 63 within a memory opening 49 constitutes a memory opening fill structure 58. The in-process source-level material layers 110′, the first-tier structure (132, 142, 170, 165), the second-tier structure (232, 242, 270, 265, 72), the inter-tier dielectric layer 180, the memory opening fill structures 58, and support pillar structures that are formed in the support openings 19 collectively constitute a memory-level assembly.

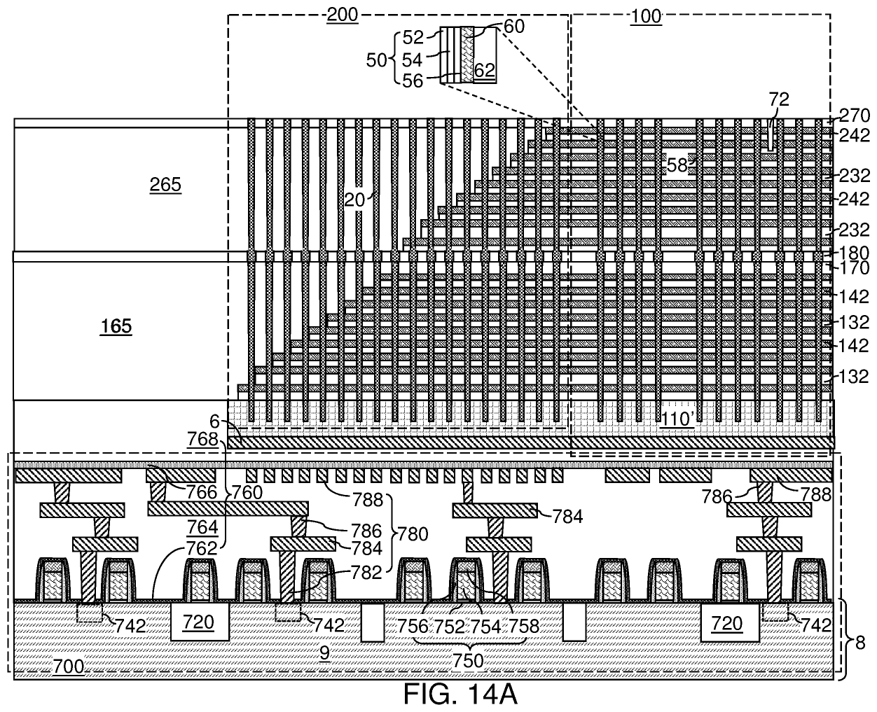

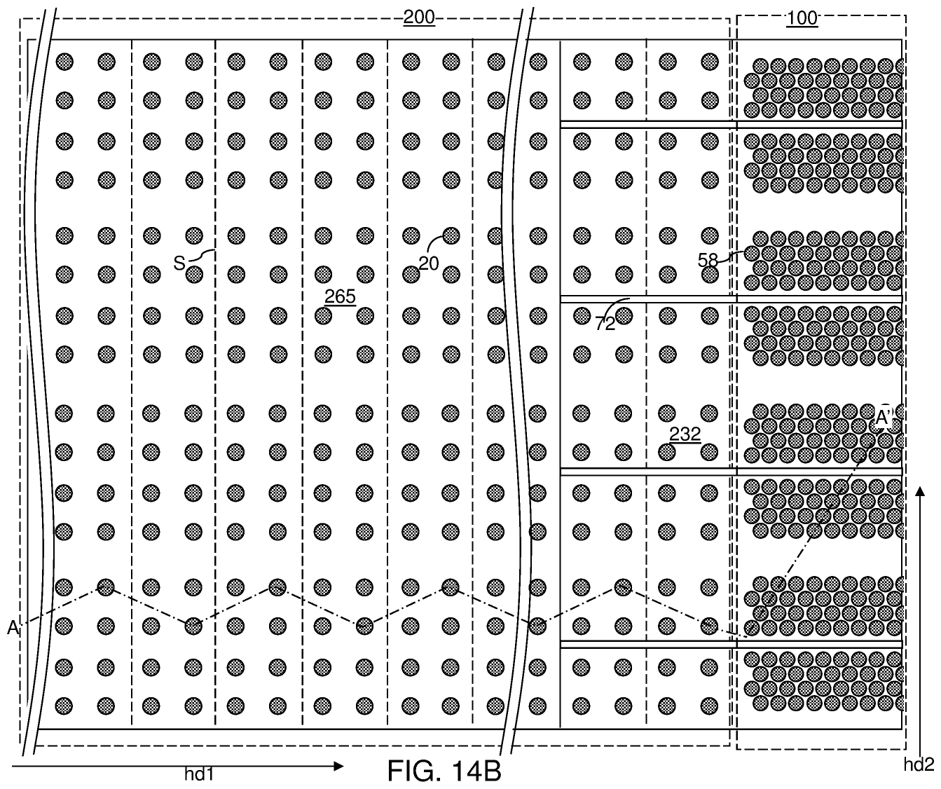

Referring to FIGS. 14A and 14B, the exemplary structure is illustrated after formation of the memory opening fill structures 58. Support pillar structures 20 are formed in the support openings 19 concurrently with formation of the memory opening fill structures 58. Each support pillar structure 20 may have a same set of components as a memory opening fill structure 58.

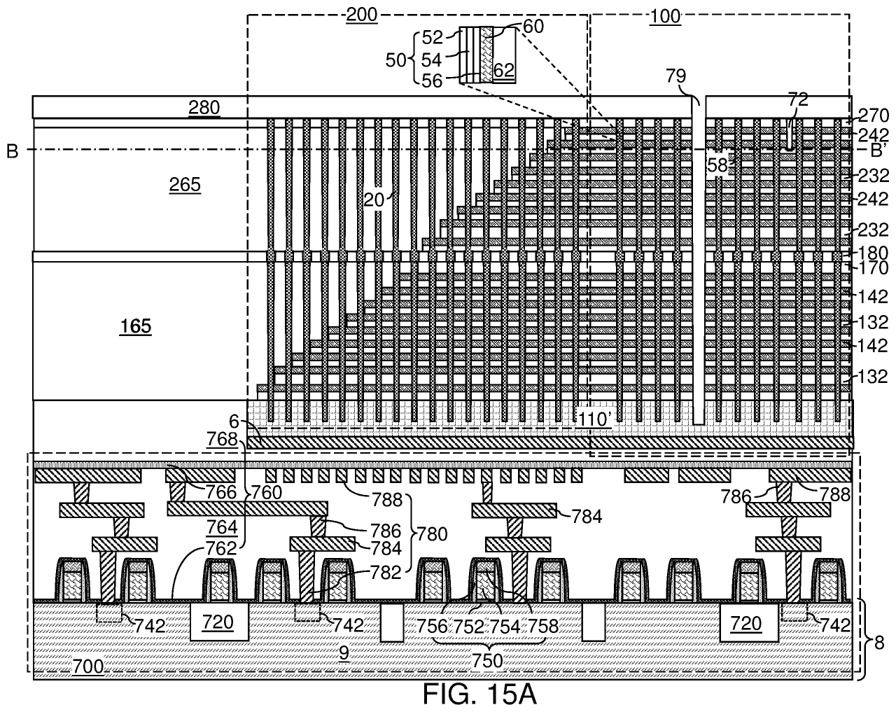

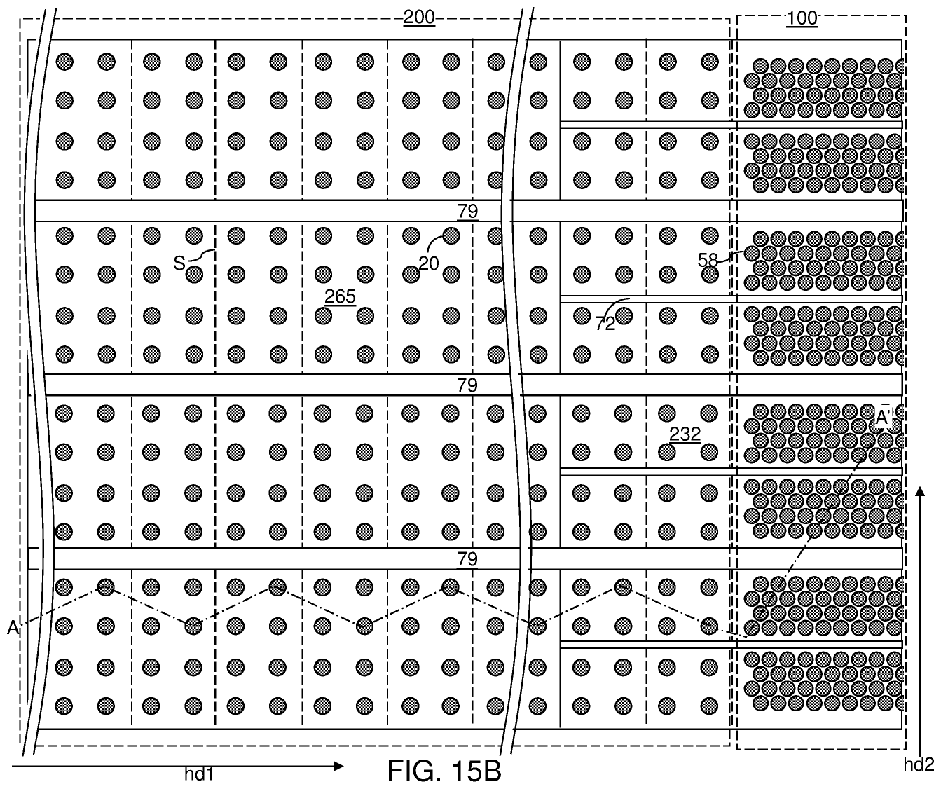

Referring to FIGS. 15A and 15B, a first contact-level dielectric layer 280 may be formed over the second-tier structure (232, 242, 270, 265, 72). The first contact-level dielectric layer 280 includes a dielectric material such as silicon oxide, and may be formed by a conformal or non-conformal deposition process. For example, the first contact-level dielectric layer 280 may include undoped silicate glass and may have a thickness in a range from 100 nm to 600 nm, although lesser and greater thicknesses may also be used.

A photoresist layer may be applied over the first contact-level dielectric layer 280 and may be lithographically patterned to form elongated openings that extend along the first horizontal direction hd1 between clusters of memory opening fill structures 58. Backside trenches 79 may be formed by transferring the pattern in the photoresist layer (not shown) through the first contact-level dielectric layer 280, the second-tier structure (232, 242, 270, 265, 72), and the first-tier structure (132, 142, 170, 165), and into the in-process source-level material layers 110′. Portions of the first contact-level dielectric layer 280, the second-tier structure (232, 242, 270, 265, 72), the first-tier structure (132, 142, 170, 165), and the in-process source-level material layers 110′ that underlie the openings in the photoresist layer may be removed to form the backside trenches 79. In one embodiment, the backside trenches 79 may be formed between clusters of memory stack structures 55. The clusters of the memory stack structures 55 may be laterally spaced apart along the second horizontal direction hd2 by the backside trenches 79.

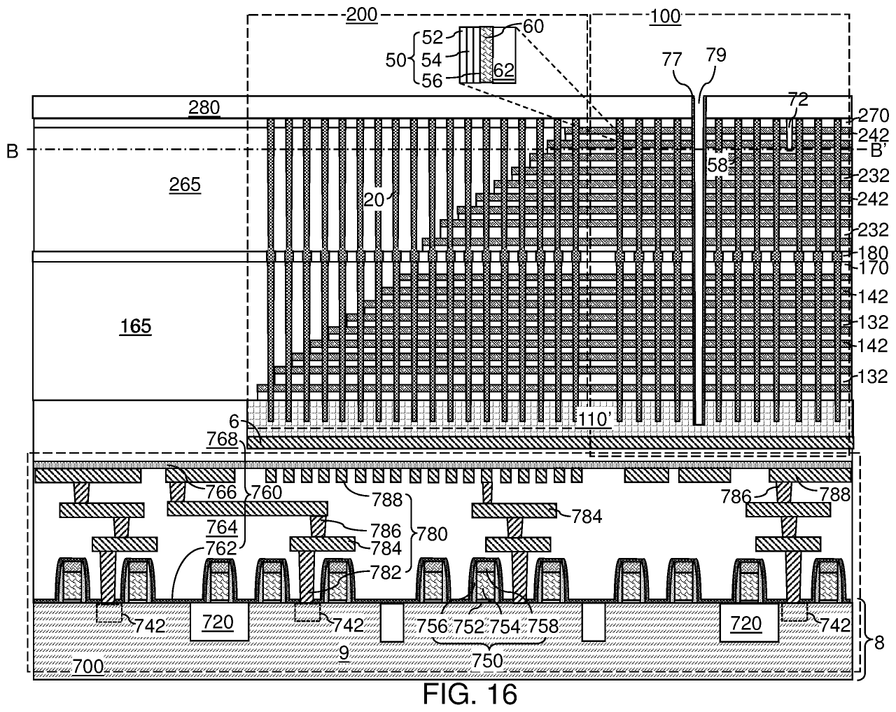

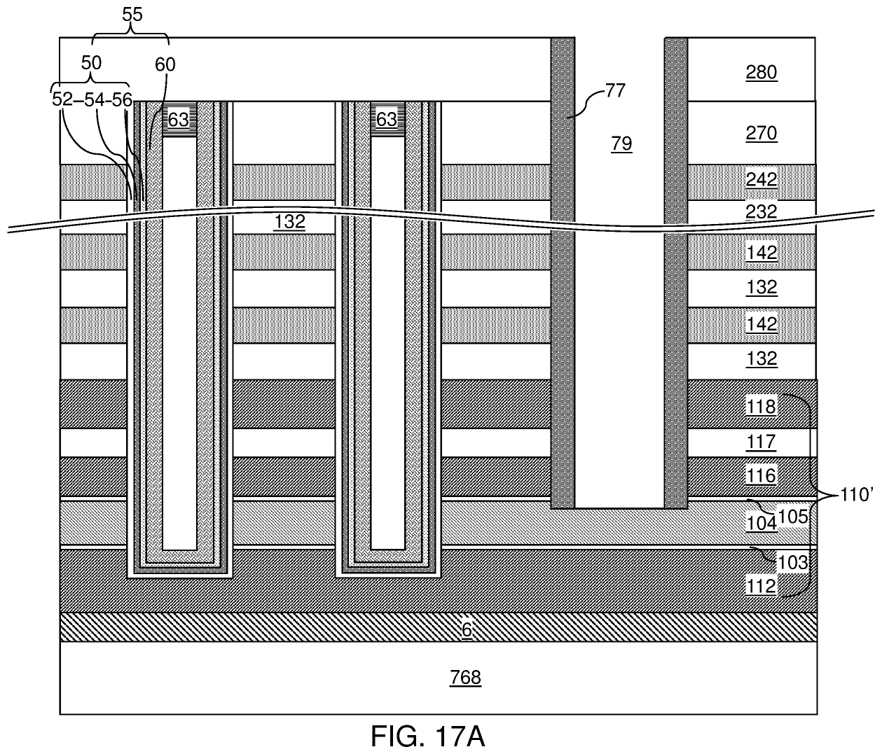

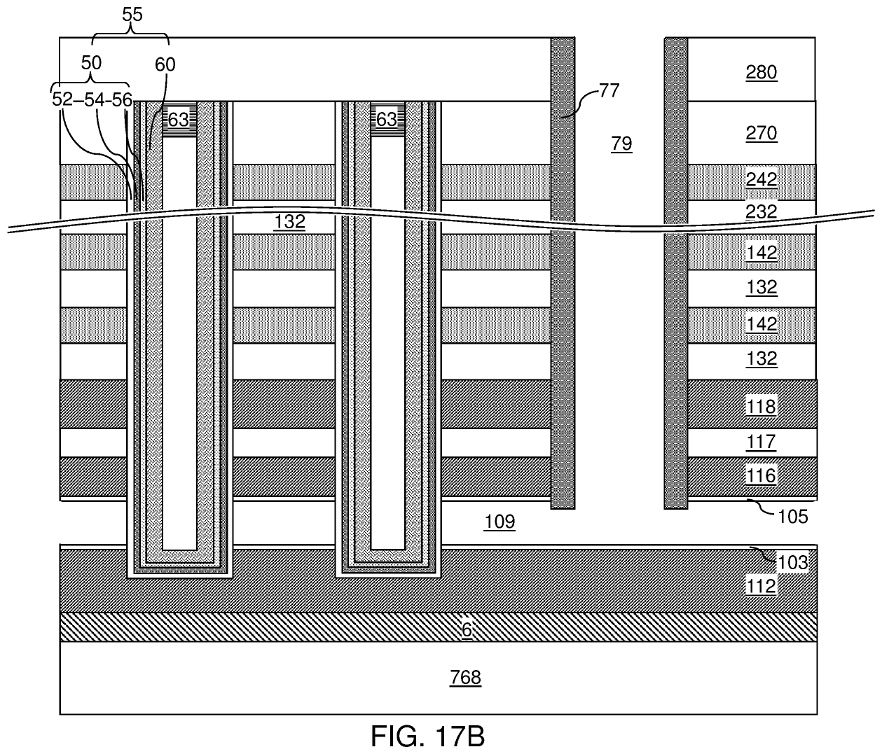

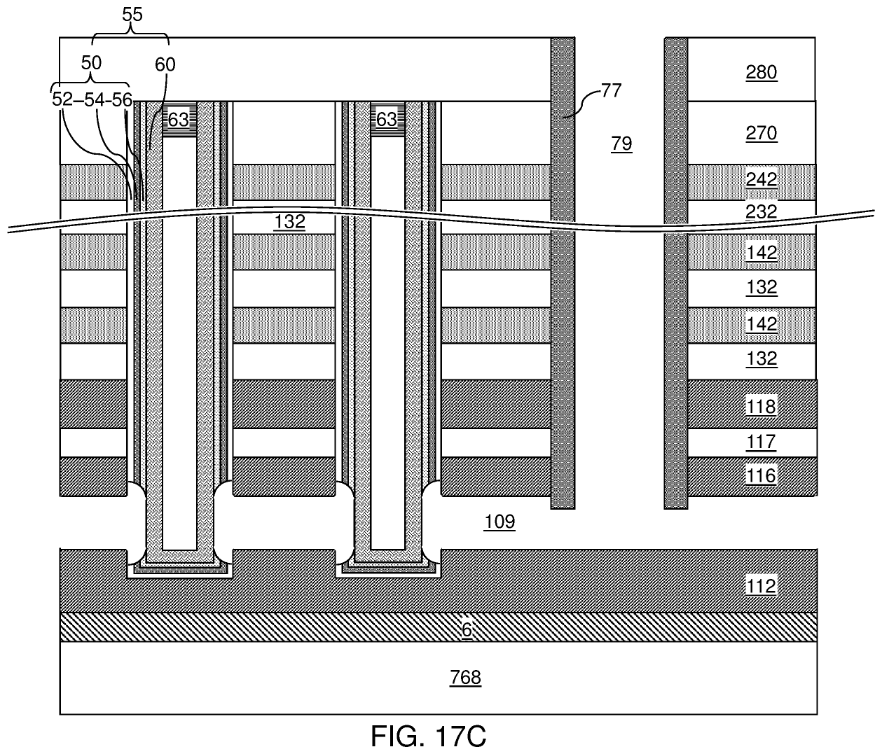

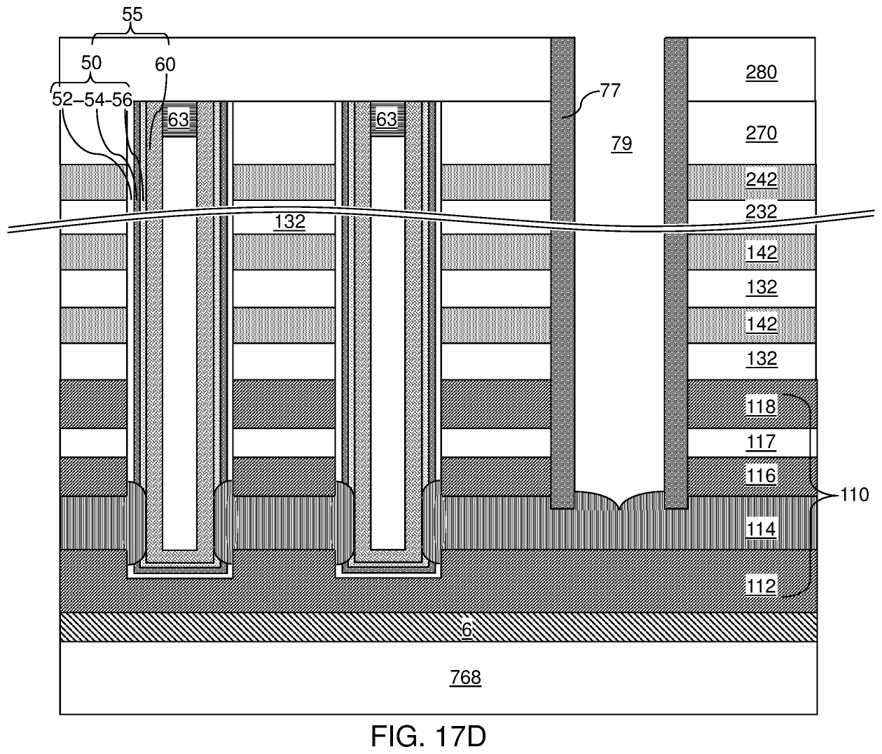

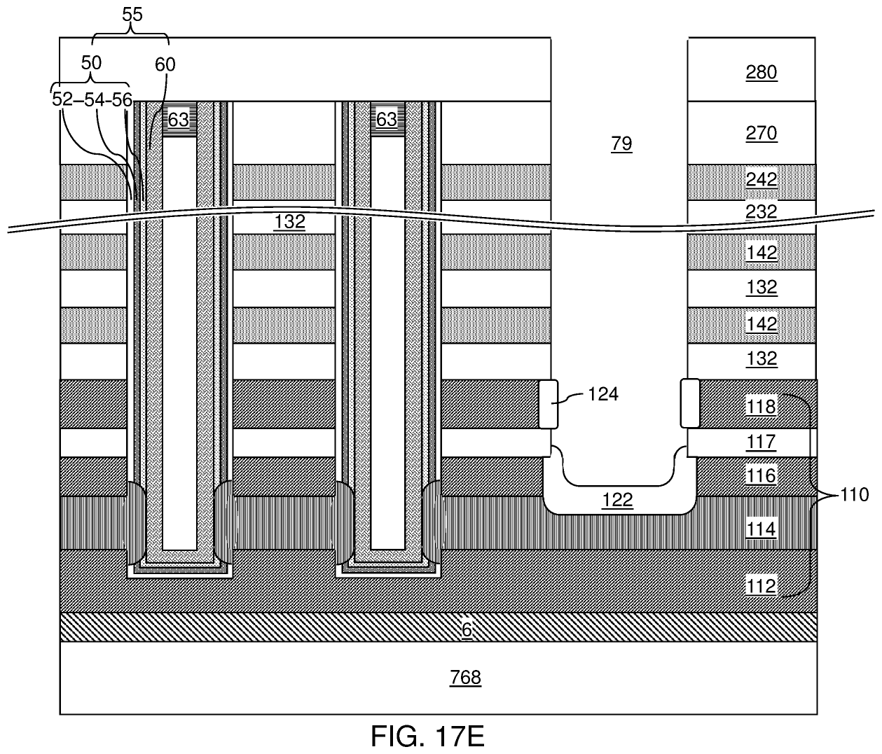

Referring to FIGS. 16 and 17A, a backside trench spacer 77 may be formed on sidewalls of each backside trench 79. For example, a conformal spacer material layer may be deposited in the backside trenches 79 and over the first contact-level dielectric layer 280, and may be anisotropically etched to form the backside trench spacers 77. The backside trench spacers 77 include a material that is different from the material of the source-level sacrificial layer 104. For example, the backside trench spacers 77 may include silicon nitride.

Referring to FIG. 17B, an etchant that etches the material of the source-level sacrificial layer 104 selective to the materials of the first-tier alternating stack (132, 142), the second-tier alternating stack (232, 242), the first and second insulating cap layers (170, 270), the first contact-level dielectric layer 280, the upper sacrificial liner 105, and the lower sacrificial liner 103 may be introduced into the backside trenches in an isotropic etch process. For example, if the source-level sacrificial layer 104 includes undoped amorphous silicon or an undoped amorphous silicon-germanium alloy, the backside trench spacers 77 include silicon nitride, and the upper and lower sacrificial liners (105, 103) include silicon oxide, a wet etch process using hot trimethyl-2 hydroxyethyl ammonium hydroxide (“hot TMY”) or tetramethyl ammonium hydroxide (TMAH) may be used to remove the source-level sacrificial layer 104 selective to the backside trench spacers 77 and the upper and lower sacrificial liners (105, 103). A source cavity 109 is formed in the volume from which the source-level sacrificial layer 104 is removed.

Wet etch chemicals such as hot TMY and TMAH are selective to doped semiconductor materials such as the p-doped semiconductor material and/or the n-doped semiconductor material of the upper source-level semiconductor layer 116 and the lower source-level semiconductor layer 112. Thus, use of selective wet etch chemicals such as hot TMY and TMAH for the wet etch process that forms the source cavity 109 provides a large process window against etch depth variation during formation of the backside trenches 79. Specifically, even if sidewalls of the upper source-level semiconductor layer 116 are physically exposed or even if a surface of the lower source-level semiconductor layer 112 is physically exposed upon formation of the source cavity 109 and/or the backside trench spacers 77, collateral etching of the upper source-level semiconductor layer 116 and/or the lower source-level semiconductor layer 112 is minimal, and the structural change to the exemplary structure caused by accidental physical exposure of the surfaces of the upper source-level semiconductor layer 116 and/or the lower source-level semiconductor layer 112 during manufacturing steps do not result in device failures. Each of the memory opening fill structures 58 is physically exposed to the source cavity 109. Specifically, each of the memory opening fill structures 58 includes a sidewall and that are physically exposed to the source cavity 109.

Referring to FIG. 17C, a sequence of isotropic etchants, such as wet etchants, may be applied to the physically exposed portions of the memory films 50 to sequentially etch the various component layers of the memory films 50 from outside to inside, and to physically expose cylindrical surfaces of the vertical semiconductor channels 60 at the level of the source cavity 109. The upper and lower sacrificial liners (105, 103) may be collaterally etched during removal of the portions of the memory films 50 located at the level of the source cavity 109. The source cavity 109 may be expanded in volume by removal of the portions of the memory films 50 at the level of the source cavity 109 and the upper and lower sacrificial liners (105, 103). A top surface of the lower source-level semiconductor layer 112 and a bottom surface of the upper source-level semiconductor layer 116 may be physically exposed to the source cavity 109. The source cavity 109 is formed by isotropically etching the source-level sacrificial layer 104 and a bottom portion of each of the memory films 50 selective to at least one source-level semiconductor layer (such as the lower source-level semiconductor layer 112 and the upper source-level semiconductor layer 116) and the vertical semiconductor channels 60.

Referring to FIG. 17D, a semiconductor material having a doping of the second conductivity type may be deposited on the physically exposed semiconductor surfaces around the source cavity 109. The physically exposed semiconductor surfaces include bottom portions of outer sidewalls of the vertical semiconductor channels 60 and a horizontal surface of the at least one source-level semiconductor layer (such as a bottom surface of the upper source-level semiconductor layer 116 and/or a top surface of the lower source-level semiconductor layer 112). For example, the physically exposed semiconductor surfaces may include the bottom portions of outer sidewalls of the vertical semiconductor channels 60, the top horizontal surface of the lower source-level semiconductor layer 112, and the bottom surface of the upper source-level semiconductor layer 116.

In one embodiment, the doped semiconductor material of the second conductivity type may be deposited on the physically exposed semiconductor surfaces around the source cavity 109 by a selective semiconductor deposition process. A semiconductor precursor gas, an etchant, and a dopant gas may be flowed concurrently into a process chamber including the exemplary structure during the selective semiconductor deposition process. For example, the semiconductor precursor gas may include silane, disilane, or dichlorosilane, the etchant gas may include gaseous hydrogen chloride, and the dopant gas may include a hydride of a dopant atom such as phosphine, arsine, stibine, or diborane. In this case, the selective semiconductor deposition process grows a doped semiconductor material having a doping of the second conductivity type from physically exposed semiconductor surfaces around the source cavity 109. The deposited doped semiconductor material forms a source contact layer 114, which may contact sidewalls of the vertical semiconductor channels 60. The atomic concentration of the dopants of the second conductivity type in the deposited semiconductor material may be in a range from 1.0×10²⁰/cm³ to 2.0×10²¹/cm³, such as from 2.0×10²⁰/cm³ to 8.0×10²⁰/cm³. The source contact layer 114 as initially formed may consist essentially of semiconductor atoms and dopant atoms of the second conductivity type. Alternatively, at least one non-selective doped semiconductor material deposition process may be used to form the source contact layer 114. Optionally, one or more etch back processes may be used in combination with a plurality of selective or non-selective deposition processes to provide a seamless and/or voidless source contact layer 114.

The duration of the selective semiconductor deposition process may be selected such that the source cavity 109 is filled with the source contact layer 114, and the source contact layer 114 contacts bottom end portions of inner sidewalls of the backside trench spacers 77. In one embodiment, the source contact layer 114 may be formed by selectively depositing a doped semiconductor material having a doping of the second conductivity type from semiconductor surfaces around the source cavity 109. In one embodiment, the doped semiconductor material may include doped polysilicon. Thus, the source-level sacrificial layer 104 may be replaced with the source contact layer 114.

The layer stack including the lower source-level semiconductor layer 112, the source contact layer 114, and the upper source-level semiconductor layer 116 constitutes a buried source layer (112, 114, 116). The set of layers including the buried source layer (112, 114, 116), the source-level insulating layer 117, and the source-select-level conductive layer 118 constitutes source-level material layers 110, which replaces the in-process source-level material layers 110′.

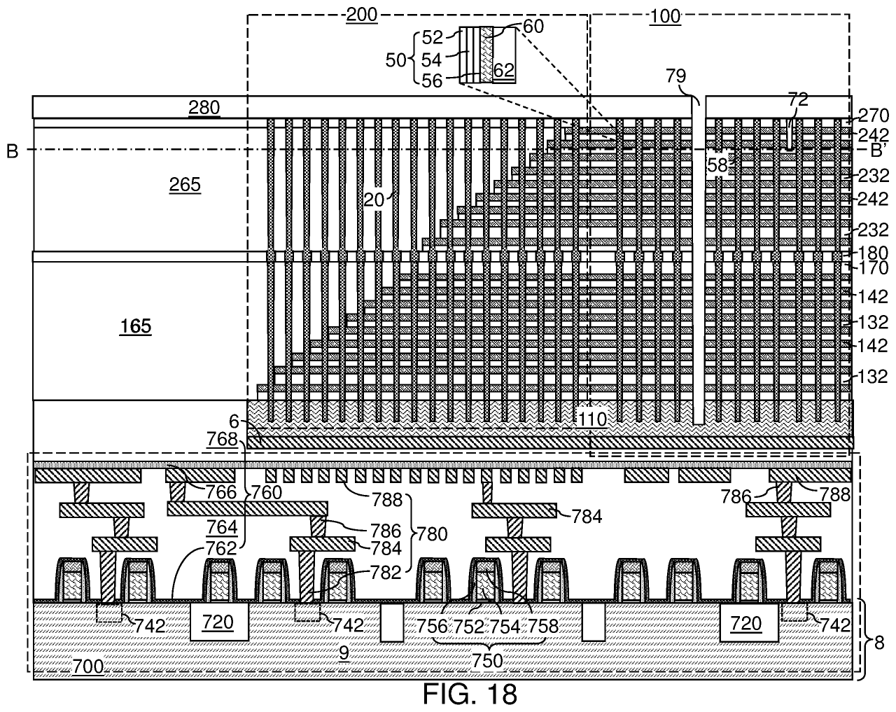

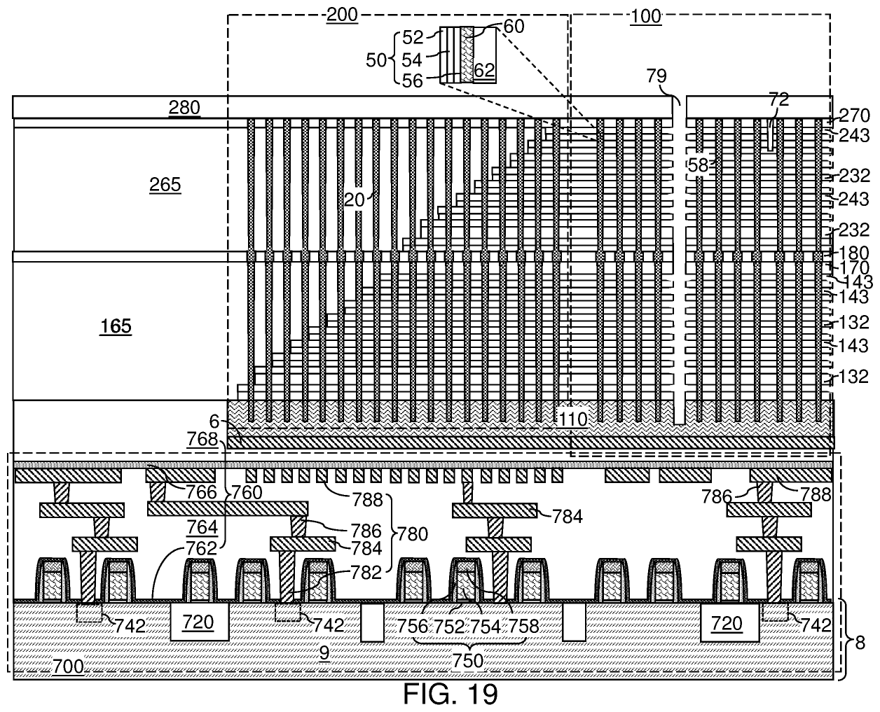

Referring to FIGS. 17E and 18, the backside trench spacers 77 may be removed selective to the insulating layers (132, 232), the first and second insulating cap layers (170, 270), the first contact-level dielectric layer 280, and the source contact layer 114 using an isotropic etch process. For example, if the backside trench spacers 77 include silicon nitride, a wet etch process using hot phosphoric acid may be performed to remove the backside trench spacers 77. In one embodiment, the isotropic etch process that removes the backside trench spacers 77 may be combined with a subsequent isotropic etch process that etches the sacrificial material layers (142, 242) selective to the insulating layers (132, 232), the first and second insulating cap layers (170, 270), the first contact-level dielectric layer 280, and the source contact layer 114.

An oxidation process may be performed to convert physically exposed surface portions of semiconductor materials into dielectric semiconductor oxide portions. For example, surfaces portions of the source contact layer 114 and the upper source-level semiconductor layer 116 may be converted into dielectric semiconductor oxide plates 122, and surface portions of the source-select-level conductive layer 118 may be converted into annular dielectric semiconductor oxide spacers 124.

Referring to FIG. 19, the sacrificial material layers (142, 242) are removed selective to the insulating layers (132, 232), the first and second insulating cap layers (170, 270), the first contact-level dielectric layer 280, and the source contact layer 114, the dielectric semiconductor oxide plates 122, and the annular dielectric semiconductor oxide spacers 124. For example, an etchant that selectively etches the materials of the sacrificial material layers (142, 242) with respect to the materials of the insulating layers (132, 232), the first and second insulating cap layers (170, 270), the retro-stepped dielectric material portions (165, 265), and the material of the outermost layer of the memory films 50 may be introduced into the backside trenches 79, for example, using an isotropic etch process. In one embodiment, the sacrificial material layers (142, 242) may include silicon nitride, the materials of the insulating layers (132, 232), the first and second insulating cap layers (170, 270), the retro-stepped dielectric material portions (165, 265), and the outermost layer of the memory films 50 may include silicon oxide materials.

The isotropic etch process may be a wet etch process using a wet etch solution, or may be a gas phase (dry) etch process in which the etchant is introduced in a vapor phase into the backside trench 79. For example, if the sacrificial material layers (142, 242) include silicon nitride, the etch process may be a wet etch process in which the exemplary structure is immersed within a wet etch tank including phosphoric acid, which etches silicon nitride selective to silicon oxide, silicon, and various other materials used in the art.

Backside recesses (143, 243) are formed in volumes from which the sacrificial material layers (142, 242) are removed. The backside recesses (143, 243) include first backside recesses 143 that are formed in volumes from which the first sacrificial material layers 142 are removed and second backside recesses 243 that are formed in volumes from which the second sacrificial material layers 242 are removed. Each of the backside recesses (143, 243) may be a laterally extending cavity having a lateral dimension that is greater than the vertical extent of the cavity. In other words, the lateral dimension of each of the backside recesses (143, 243) may be greater than the height of the respective backside recess (143, 243). A plurality of backside recesses (143, 243) may be formed in the volumes from which the material of the sacrificial material layers (142, 242) is removed. Each of the backside recesses (143, 243) may extend substantially parallel to the top surface of the substrate semiconductor layer 9. A backside recess (143, 243) may be vertically bounded by a top surface of an underlying insulating layer (132, 232) and a bottom surface of an overlying insulating layer (132, 232). In one embodiment, each of the backside recesses (143, 243) may have a uniform height throughout.

Optionally, a backside blocking dielectric layer (not shown) may be optionally deposited in the backside recesses (143, 243) and the backside trenches 79 and over the first contact-level dielectric layer 280. The backside blocking dielectric layer includes a dielectric material such as a dielectric metal oxide, silicon oxide, or a combination thereof. For example, the backside blocking dielectric layer may include aluminum oxide. The backside blocking dielectric layer may be formed by a conformal deposition process such as atomic layer deposition or chemical vapor deposition. The thickness of the backside blocking dielectric layer may be in a range from 1 nm to 20 nm, such as from 2 nm to 10 nm, although lesser and greater thicknesses may also be used.

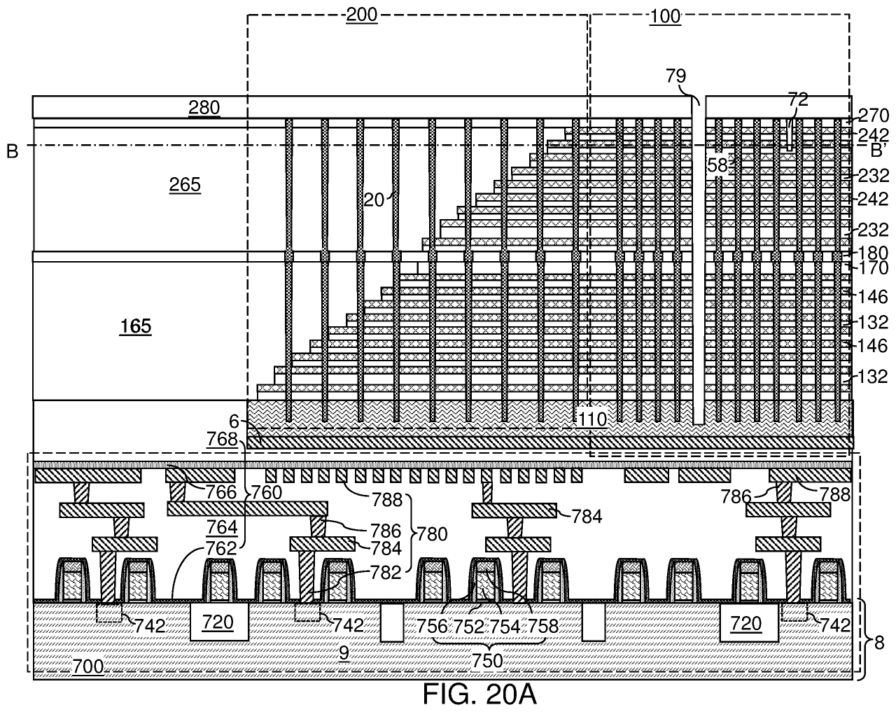

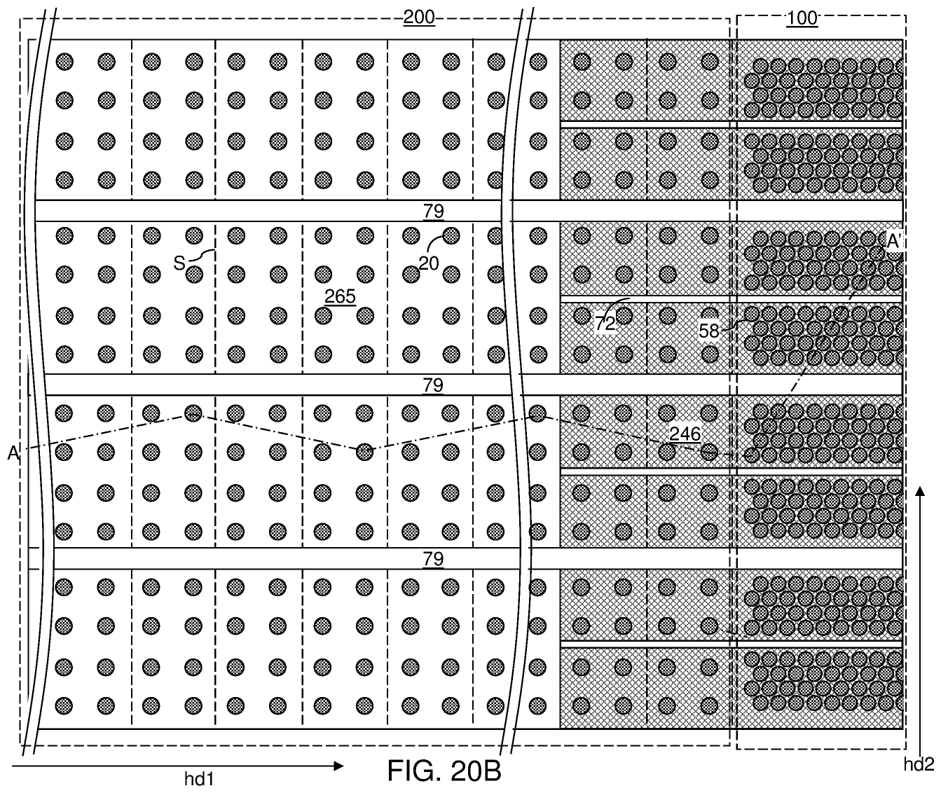

Referring to FIGS. 20A and 20B, at least one conductive material may be deposited in the plurality of backside recesses (143, 243), on the sidewalls of the backside trenches 79, and over the first contact-level dielectric layer 280. The at least one conductive material may be deposited by a conformal deposition method, which may be, for example, chemical vapor deposition (CVD), atomic layer deposition (ALD), electroless plating, electroplating, or a combination thereof. The at least one conductive material may include an elemental metal, an intermetallic alloy of at least two elemental metals, a conductive nitride of at least one elemental metal, a conductive metal oxide, a conductive doped semiconductor material, a conductive metal-semiconductor alloy such as a metal silicide, alloys thereof, and combinations or stacks thereof.

In one embodiment, the at least one conductive material may include at least one metallic material, i.e., an electrically conductive material that includes at least one metallic element. Non-limiting exemplary metallic materials that may be deposited in the backside recesses (143, 243) include tungsten, tungsten nitride, titanium, titanium nitride, tantalum, tantalum nitride, cobalt, and ruthenium. For example, the at least one conductive material may include a conductive metallic nitride liner that includes a conductive metallic nitride material such as TiN, TaN, WN, or a combination thereof, and a conductive fill material such as W, Co, Ru, Mo, Cu, or combinations thereof. In one embodiment, the at least one conductive material for filling the backside recesses (143, 243) may be a combination of titanium nitride layer and a tungsten fill material.

Electrically conductive layers (146, 246) may be formed in the backside recesses (143, 243) by deposition of the at least one conductive material. A plurality of first electrically conductive layers 146 may be formed in the plurality of first backside recesses 143, a plurality of second electrically conductive layers 246 may be formed in the plurality of second backside recesses 243, and a continuous metallic material layer (not shown) may be formed on the sidewalls of each backside trench 79 and over the first contact-level dielectric layer 280. Each of the first electrically conductive layers 146 and the second electrically conductive layers 246 may include a respective conductive metallic nitride liner and a respective conductive fill material. Thus, the first and second sacrificial material layers (142, 242) may be replaced with the first and second electrically conductive layers (146, 246), respectively. Specifically, each first sacrificial material layer 142 may be replaced with an optional portion of the backside blocking dielectric layer and a first electrically conductive layer 146, and each second sacrificial material layer 242 may be replaced with an optional portion of the backside blocking dielectric layer and a second electrically conductive layer 246. A backside cavity is present in the portion of each backside trench 79 that is not filled with the continuous metallic material layer.

Residual conductive material may be removed from inside the backside trenches 79. Specifically, the deposited metallic material of the continuous metallic material layer may be etched back from the sidewalls of each backside trench 79 and from above the first contact-level dielectric layer 280, for example, by an anisotropic or isotropic etch. Each remaining portion of the deposited metallic material in the first backside recesses constitutes a first electrically conductive layer 146. Each remaining portion of the deposited metallic material in the second backside recesses constitutes a second electrically conductive layer 246. Sidewalls of the first electrically conductive material layers 146 and the second electrically conductive layers may be physically exposed to a respective backside trench 79. The backside trenches may have a pair of curved sidewalls having a non-periodic width variation along the first horizontal direction hd1 and a non-linear width variation along the vertical direction.

Each electrically conductive layer (146, 246) may be a conductive sheet including openings therein. A first subset of the openings through each electrically conductive layer (146, 246) may be filled with memory opening fill structures 58. A second subset of the openings through each electrically conductive layer (146, 246) may be filled with the support pillar structures 20. Each electrically conductive layer (146, 246) may have a lesser area than any underlying electrically conductive layer (146, 246) because of the first and second stepped surfaces. Each electrically conductive layer (146, 246) may have a greater area than any overlying electrically conductive layer (146, 246) because of the first and second stepped surfaces.

In some embodiment, drain-select-level isolation structures 72 may be provided at topmost levels of the second electrically conductive layers 246. A subset of the second electrically conductive layers 246 located at the levels of the drain-select-level isolation structures 72 constitutes drain select gate electrodes. A subset of the electrically conductive layer (146, 246) located underneath the drain select gate electrodes may function as combinations of a control gate and a word line located at the same level. The control gate electrodes within each electrically conductive layer (146, 246) are the control gate electrodes for a vertical memory device including the memory stack structure 55.

Each of the memory stack structures 55 comprises a vertical stack of memory elements located at each level of the electrically conductive layers (146, 246). A subset of the electrically conductive layers (146, 246) may comprise word lines for the memory elements. The semiconductor devices in the underlying peripheral device region 700 may comprise word line switch devices configured to control a bias voltage to respective word lines. The memory-level assembly is located over the substrate semiconductor layer 9. The memory-level assembly includes at least one alternating stack (132, 146, 232, 246) and memory stack structures 55 vertically extending through the at least one alternating stack (132, 146, 232, 246).

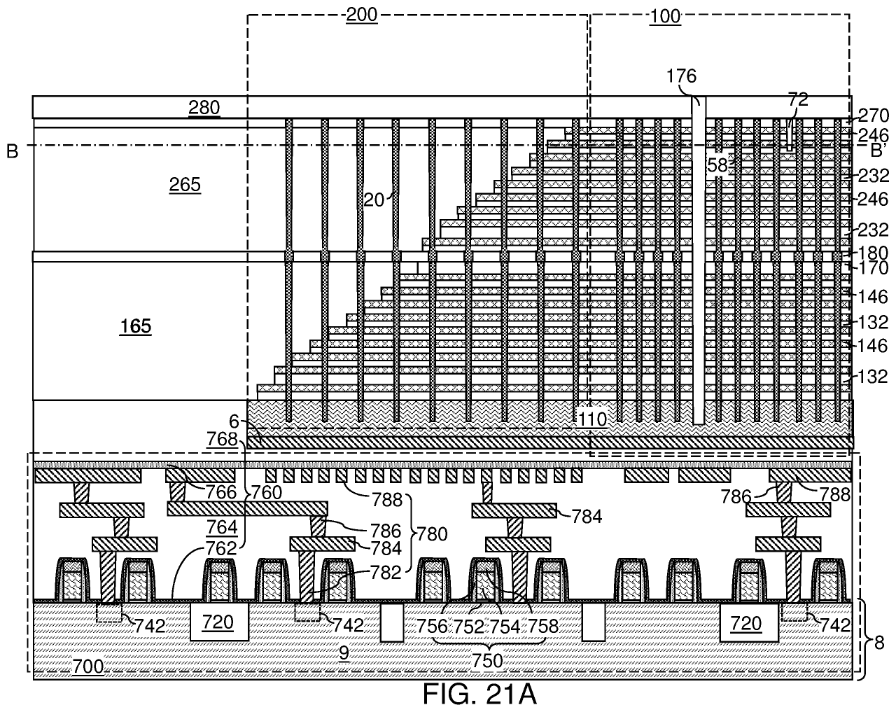

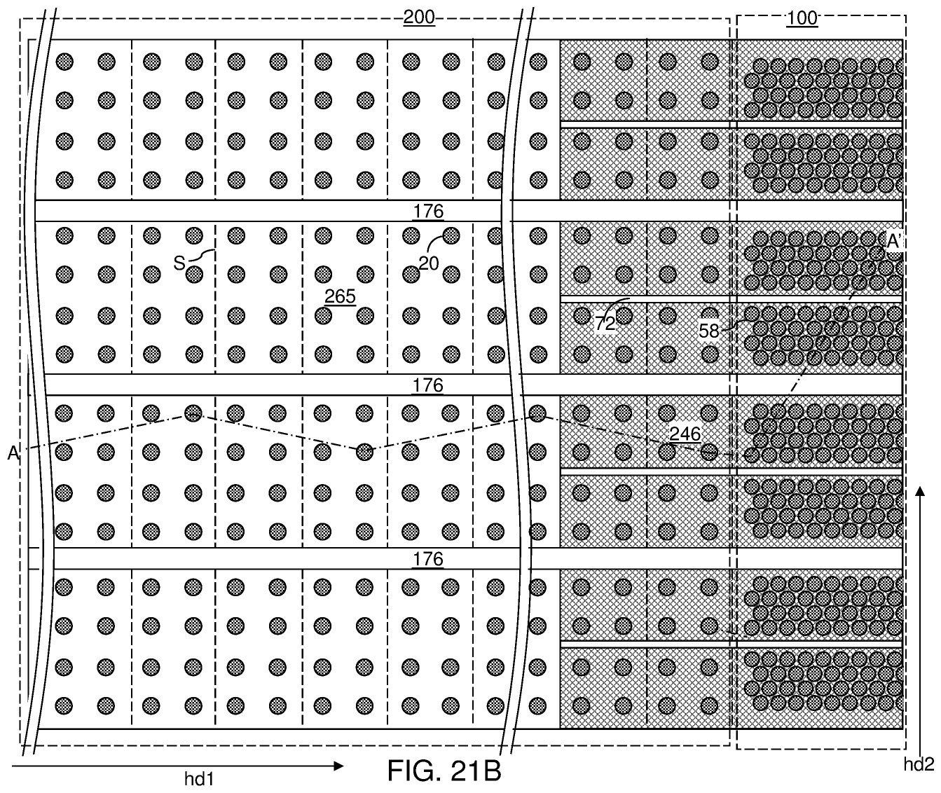

Referring to FIGS. 21A and 21B, a dielectric material layer may be conformally deposited in the backside trenches 79 and over the first contact-level dielectric layer 280 by a conformal deposition process. The dielectric material layer may include, for example, silicon oxide.

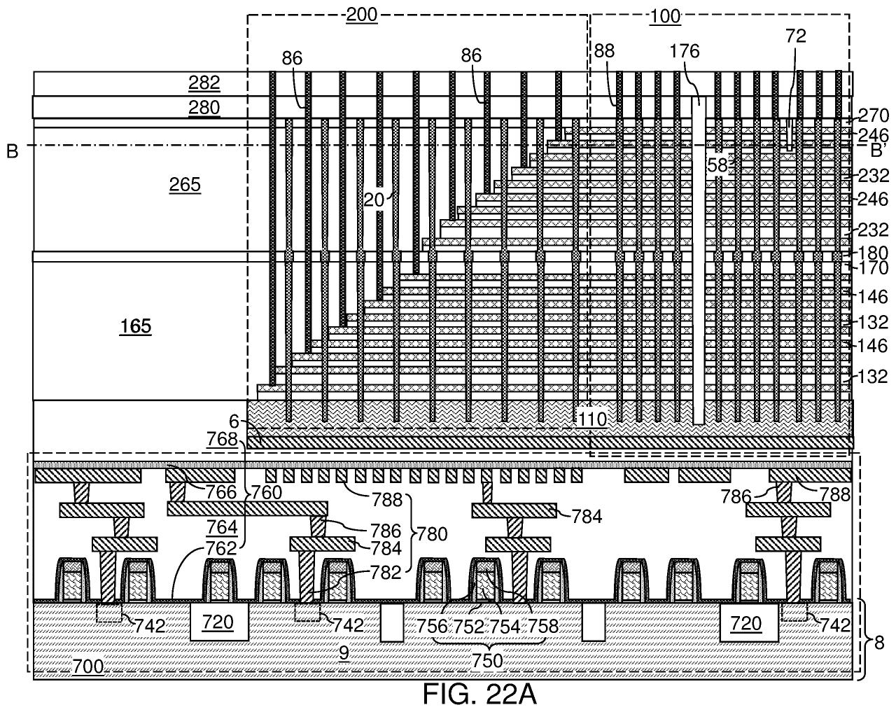

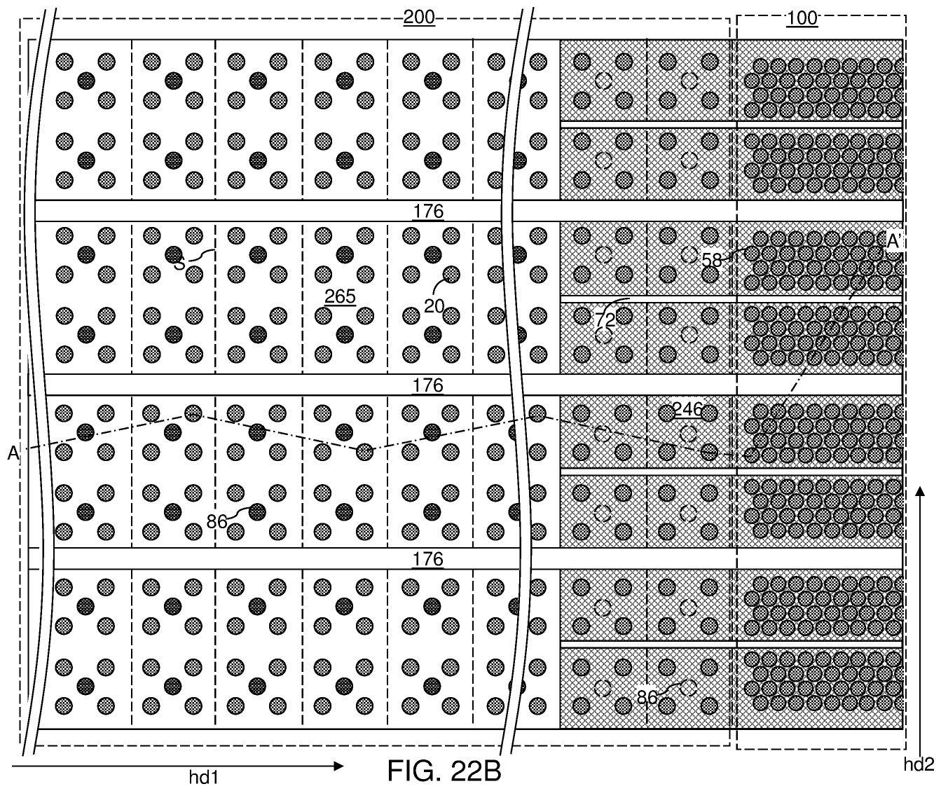

Referring to FIGS. 22A and 22B, a second contact-level dielectric layer 282 may be formed over the first contact-level dielectric layer 280. The second contact-level dielectric layer 282 includes a dielectric material such as silicon oxide, and may have a thickness in a range from 100 nm to 600 nm, although lesser and greater thicknesses may also be used.

A photoresist layer (not shown) may be applied over the second contact-level dielectric layer 282, and may be lithographically patterned to form various contact via openings. For example, openings for forming drain contact via structures may be formed in the memory array region 100, and openings for forming staircase region contact via structures may be formed in the staircase region 200. An anisotropic etch process is performed to transfer the pattern in the photoresist layer through the second and first contact-level dielectric layers (282, 280) and underlying dielectric material portions. The drain regions 63 and the electrically conductive layers (146, 246) may be used as etch stop structures. Drain contact via cavities may be formed over each drain region 63, and staircase-region contact via cavities may be formed over each electrically conductive layer (146. 246) at the stepped surfaces underlying the first and second retro-stepped dielectric material portions (165, 265). The photoresist layer may be subsequently removed, for example, by ashing.

Drain contact via structures 88 are formed in the drain contact via cavities and on a top surface of a respective one of the drain regions 63. Staircase-region contact via structures 86 are formed in the staircase-region contact via cavities and on a top surface of a respective one of the electrically conductive layers (146, 246). The staircase-region contact via structures 86 may include drain select level contact via structures that contact a subset of the second electrically conductive layers 246 that function as drain select level gate electrodes. Further, the staircase-region contact via structures 86 may include word line contact via structures that contact electrically conductive layers (146, 246) that underlie the drain select level gate electrodes and function as word lines for the memory stack structures 55.

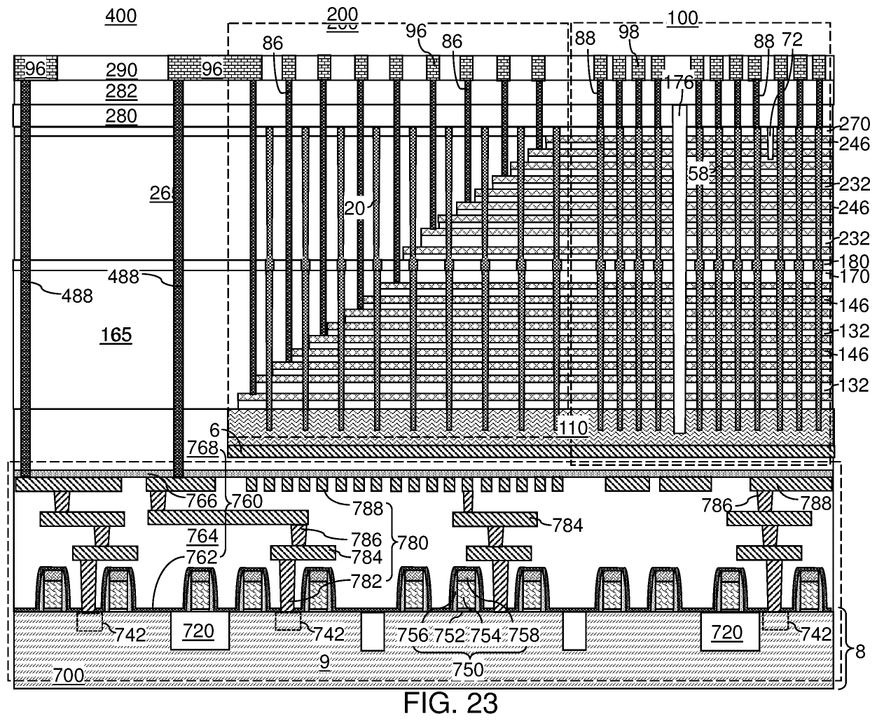

Referring to FIG. 23, peripheral-region via cavities may be formed through the second and first contact-level dielectric layers (282, 280), the second and first retro-stepped dielectric material portions (265, 165), and the at least one second dielectric layer 768 to top surfaces of a first subset of the lower-level metal interconnect structure 780 in the peripheral device region 400. Through-memory-region via cavities may be formed through the interconnection region dielectric fill material portions 584 and the at least one second dielectric layer 768 to top surfaces of a second subset of the lower-level metal interconnect structure 780. At least one conductive material may be deposited in the peripheral-region via cavities and in the through-memory-region via cavities. Excess portions of the at least one conductive material may be removed from above the horizontal plane including the top surface of the second contact-level dielectric layer 282. Each remaining portion of the at least one conductive material in a peripheral-region via cavity constitutes a peripheral-region contact via structure 488. Each remaining portion of the at least one conductive material in a through-memory-region via cavity constitutes a through-memory-region via structure 588.

At least one additional dielectric layer may be formed over the contact-level dielectric layers (280, 282), and additional metal interconnect structures (herein referred to as upper-level metal interconnect structures) may be formed in the at least one additional dielectric layer. For example, the at least one additional dielectric layer may include a line-level dielectric layer 290 that is formed over the contact-level dielectric layers (280, 282). The upper-level metal interconnect structures may include bit lines 98 contacting a respective one of the drain contact via structures 88, and interconnection line structures 96 contacting, and/or electrically connected to, at least one of the staircase-region contact via structures 86 and/or the peripheral-region contact via structures 488 and/or the through-memory-region via structures 588. The word line contact via structures (which are provided as a subset of the staircase-region contact via structures 86) may be electrically connected to the word line driver circuit through a subset of the lower-level metal interconnect structures 780 and through a subset of the peripheral-region contact via structures 488.

In one embodiment, a method includes forming a first portion of a layer 1481 over a substrate 8 (e.g., when the substrate 8 is located in the apparatus 1000) by flowing a reactant gas past the substrate 8 in a first direction (e.g., downward), and forming a second portion of the layer 1481 on the first portion of the layer 1481 by flowing the reactant gas past the substrate 8 in a second direction (e.g., upward) different from the first direction.

In one embodiment, the reactant gas comprises an oxidant gas, such as water vapor, the forming the first portion of the layer comprises forming a first portion of a semiconductor oxide layer 1481 by oxidizing a portion of a first semiconductor layer 112 located over the substrate 8 using the oxidant gas flowing past the substrate in the first direction, and the forming the second portion of the layer 1481 comprises forming a second portion of the semiconductor oxide layer 1481 using the oxidant gas flowing past the substrate 8 in the second direction. In one embodiment, the first semiconductor layer 112 comprises a silicon layer, the semiconductor oxide layer 1481 comprises a silicon oxide layer, and the second direction is opposite to the first direction.

In one embodiment, the method also includes providing a stack of substrates 620 comprising the substrate 8 and a plurality of additional substrates into a vacuum chamber 600, forming the first portion of the layer 1481 over the stack of substrates 620 by flowing the reactant gas past the stack of substrates in the first direction, and forming the second portion of the layer 1481 on the first portion of the layer by flowing the reactant gas past the stack of substrates 620 in the second direction.

While in the above embodiments, sacrificial semiconductor oxide portions (1481, 1482, 1483) are formed, the apparatus 1000 of the embodiments of present disclosure can provide enhanced wafer-to-wafer layer thickness uniformity in a batch layer formation process by employing two different flow configurations in which the reactant gas flows in opposite directions in any reaction process employing a flow of a reactant gas. The apparatus of the embodiments of the present disclosure may be employed for an oxidation process, a nitridation process, or a deposition process (e.g., a CVD process). Therefore, in one embodiment, the reactant gas comprises ammonia, the forming the first portion of the layer comprises forming a first portion of a semiconductor nitride layer by nitriding a portion of a first semiconductor layer located over the substrate using the ammonia flowing past the substrate in the first direction, and the forming the second portion of the layer comprises forming a second portion of the semiconductor nitride layer using the ammonia flowing past the substrate in the second direction. In another embodiment, the reactant gas comprises a chemical vapor deposition (CVD) source gas, the forming the first portion of the layer comprises depositing the first portion of the layer by CVD using the source gas flowing past the substrate in the first direction, and the forming the second portion of the layer comprises depositing the second portion of the layer by CVD using the source gas flowing past the substrate in the second direction.

Although the foregoing refers to particular embodiments, it will be understood that the disclosure is not so limited. It will occur to those of ordinary skill in the art that various modifications may be made to the disclosed embodiments and that such modifications are intended to be within the scope of the disclosure. Compatibility is presumed among all embodiments that are not alternatives of one another. The word “comprise” or “include” contemplates all embodiments in which the word “consist essentially of” or the word “consists of” replaces the word “comprise” or “include,” unless explicitly stated otherwise. Where an embodiment using a particular structure and/or configuration is illustrated in the present disclosure, it is understood that the present disclosure may be practiced with any other compatible structures and/or configurations that are functionally equivalent provided that such substitutions are not explicitly forbidden or otherwise known to be impossible to one of ordinary skill in the art. All of the publications, patent applications and patents cited herein are incorporated herein by reference in their entirety.

What is claimed is:

1. A method, comprising:
forming a first portion of a layer over a substrate by flowing a reactant gas past the substrate in a first direction; and
forming a second portion of the layer on the first portion of the layer by flowing the reactant gas past the substrate in a second direction different from the first direction.

2. The method of claim 1, wherein:
the reactant gas comprises an oxidant gas;
the forming the first portion of the layer comprises forming a first portion of a semiconductor oxide layer by oxidizing a portion of a first semiconductor layer located over the substrate using the oxidant gas flowing past the substrate in the first direction; and
the forming the second portion of the layer comprises forming a second portion of the semiconductor oxide layer using the oxidant gas flowing past the substrate in the second direction.

3. The method of claim 2, wherein:
the first semiconductor layer comprises a silicon layer;
the semiconductor oxide layer comprises a silicon oxide layer; and
the second direction is opposite to the first direction.

4. The method of claim 2, further comprising:
forming a source-level sacrificial layer over the first semiconductor layer which comprises a lower source-level semiconductor layer;
forming an upper source-level semiconductor layer over the source-level sacrificial layer;
forming a first-tier alternating stack of first insulating layers and first sacrificial material layers over the upper source-level semiconductor layer;
forming first-tier memory openings through the first-tier alternating stack, the upper source-level semiconductor layer, the source-level sacrificial layer and at least part of the lower source-level semiconductor layer;
forming sacrificial first-tier opening fill portions in the first-tier memory openings;
forming a second-tier alternating stack of second insulating layers and second sacrificial material layers over the first-tier alternating stack;
forming second-tier memory openings through the second-tier alternating stack to expose the sacrificial first-tier opening fill portions;
removing the sacrificial first-tier opening fill portions through the second-tier memory openings to form inter-tier memory openings, wherein each inter-tier memory opening comprises a combination of a respective one of the first tier-memory openings and a respective one of the second-tier memory openings;
forming memory stack structures in the inter-tier memory openings, wherein each of the memory stack structures comprises a vertical semiconductor channel and a memory film;
forming a backside trench vertically extending through the alternating stack, the upper source-level semiconductor layer, and at least part of the source-level sacrificial layer;
removing the source-level sacrificial layer through the backside trench to form a source cavity;
exposing sidewalls of the vertical semiconductor channels in the source cavity;
forming a source contact layer in the source cavity through the backside trench, wherein the source contact layer contacts the sidewalls of the vertical semiconductor channels exposed in the source cavity; and
replacing the sacrificial material layers with electrically conductive layers through the backside trench.

5. The method of claim 4, wherein forming the semiconductor oxide layer comprises forming a first sacrificial semiconductor oxide portion on a portion of the lower source-level semiconductor layer exposed in each of the first-tier memory openings.

6. The method of claim 5, wherein the sacrificial semiconductor oxide portion protects the lower source-level semiconductor layer during the step of removing the sacrificial first-tier opening fill portions.

7. The method of claim 6, further comprising forming a second sacrificial semiconductor oxide portion on a portion of the upper source-level semiconductor layer exposed in each of the first-tier memory openings simultaneously with the step of forming the first sacrificial semiconductor oxide portion on the portion of the lower source-level semiconductor layer exposed in each of the first-tier memory openings.

8. The method of claim 7, further comprising selectively removing the first and the second sacrificial semiconductor oxide portions after the step of removing the sacrificial first-tier opening fill portions and before the step of forming the memory stack structures.

9. The method of claim 2, wherein the oxidant gas comprises water vapor.

10. The method of claim 1, wherein:
the reactant gas comprises ammonia;
the forming the first portion of the layer comprises forming a first portion of a semiconductor nitride layer by nitriding a portion of a first semiconductor layer located over the substrate using the ammonia flowing past the substrate in the first direction; and
the forming the second portion of the layer comprises forming a second portion of the semiconductor nitride layer using the ammonia flowing past the substrate in the second direction.

11. The method of claim 1, wherein:
the reactant gas comprises a chemical vapor deposition (CVD) source gas;
the forming the first portion of the layer comprises depositing the first portion of the layer by CVD using the source gas flowing past the substrate in the first direction; and
the forming the second portion of the layer comprises depositing the second portion of the layer by CVD using the source gas flowing past the substrate in the second direction.

12. The method of claim 1, further comprising:
providing a stack of substrates comprising the substrate and a plurality of additional substrates into a vacuum chamber;
forming the first portion of the layer over the stack of substrates by flowing the reactant gas past the stack of substrates in the first direction; and
forming the second portion of the layer on the first portion of the layer by flowing the reactant gas past the stack of substrates in the second direction.

13. An apparatus, comprising:
a vacuum chamber extending in a first direction and having a first orifice located at a first end of the vacuum chamber and a second orifice located proximate to a second end of the vacuum chamber;
a wafer boat extending along the first direction in the vacuum chamber and configured to hold wafers thereupon;
a gas distribution conduit having a first gas outlet and a second gas outlet that are fluidly connected in parallel;
a first gas flow switch connected to the first gas outlet and a first connection port fluidly connected to the first orifice;
a second gas flow switch connected to the second gas outlet and a second connection port fluidly connected to the second orifice; and
a process controller configured to control the first gas flow switch and the second gas flow switch to provide:
a first gas flow configuration in which the reactant gas flows from the first gas outlet, through the first gas flow switch and the first connection port, and toward the first orifice; and
a second gas flow configuration in which the reactant gas flows from the second gas outlet, through the second gas flow switch and the second connection port, and toward the second orifice.

14. The apparatus of claim 13, wherein the reactant gas flows downwards past the wafer boat in the first gas flow configuration and the reactant gas flows upwards past the wafer boat in the second gas flow configuration.

15. The apparatus of claim 13, further comprising a vacuum pump fluidly connected to a vacuum conduit and having a first vacuum inlet port and a second vacuum inlet port, wherein the first gas flow switch is also fluidly connected to the first vacuum inlet port, and the second gas flow switch is also fluidly connected to the second vacuum inlet port.

16. The apparatus of claim 15, wherein:
the first gas flow switch disconnects a first fluid flow path between the first vacuum inlet port and the first connection port in the first gas flow configuration; and
the second gas flow switch connects a second fluid flow path between the second vacuum inlet port and the second connection port in the first gas flow configuration.

17. The apparatus of claim 16, wherein:
the first gas flow switch connects the first fluid flow path between the first vacuum inlet port and the first connection port in the second gas flow configuration; and
the second gas flow switch disconnects the second fluid flow path between the second vacuum inlet port and the second connection port in the second gas flow configuration.

18. The apparatus of claim 17, wherein:
the second gas flow switch disconnects a fluid flow path between the second gas outlet and the second connection port in the first gas flow configuration; and
the first gas flow switch disconnects a fluid flow path between the first gas outlet and the first connection port in the second gas flow configuration.

19. The apparatus of claim 13, further comprising a water vapor generator fluidly connected to an inlet of the gas distribution conduit.

20. The apparatus of claim 13, wherein the vacuum chamber comprises an outer chamber portion fluidly connected to the first orifice, an inner chamber portion fluidly connected to the first and the second orifices, and a bottom chamber portion fluidly connected to the second orifice.
